(19) United States
(12) Patent Application Publication
(10) Pub. No.: US 2007/0200177 A1
(43) Pub. Date: Aug. 30, 2007

(54) Semiconductor laser device and semiconductor laser device manufacturing method

(75) Inventors: Masayuki Hata, Osaka (JP); Takashi Kano, Osaka (JP)

Correspondence Address: NDQ&M WATCHSTONE LLP, 1300 EYE STREET, NW, SUITE 1000 WEST TOWER, WASHINGTON, DC, 20005, US

(73) Assignee: Sanyo Electric Co., Ltd., Moriguchi (JP)

(21) Appl. No.: 11/711,051

(22) Filed: Feb. 27, 2007

(30) Foreign Application Priority Data
Feb. 28, 2006 (JP) P2006-054079
Dec. 28, 2006 (JP) P2006-356579

(51) Int. Cl. H01L 27/12

(52) U.S. Cl. 257/347

(57) ABSTRACT

A semiconductor laser device comprising: an active layer, a semiconductor layer formed on the active layer and having a wurtzite structure, wherein a principal surface of the active layer is substantially perpendicular to a (0001) surface of the semiconductor layer, a current path portion in the semiconductor layer extends along a crystal orientation substantially parallel to the (0001) surface of the semiconductor layer, and an inner angle of the principal surface to a first side surface is different from an inner angle of the principal surface to a second side surface, the first side surface is a side surface of the current path portion and the second side surface is opposite to the first side surface.

### CROSS REFERENCE TO RELATED APPLICATIONS

This application is based upon and claims the benefit of priority from prior Japanese Patent Application No. 2006-54079, filed on Feb. 28, 2006; and prior Japanese Patent Application No. 2006-356579, filed on Dec. 28, 2006; the entire contents of which are incorporated herein by reference.

### BACKGROUND OF THE INVENTION

1. Field of the Invention

The present invention relates to a semiconductor laser device and a semiconductor laser device manufacturing method.

2. Description of the Related Art

Conventionally, there is a known semiconductor laser device having a semiconductor layer formed on an active layer thereof, with a projective ridge portion for current confinement formed. When the width of the ridge portion increases, a horizontal transverse mode tends to change from a fundamental mode to a higher-order mode whose order is first or higher at the time of laser oscillation. Thus, when the horizontal transverse mode changes to the higher-order mode, a kink will occur in a current-optical output characteristics. Accordingly, conventionally, there is proposed a technique of suppressing a horizontal transverse mode from changing to a higher-order mode at the time of laser oscillation in order to prevent occurrence of a kink.

Moreover, there is proposed a technique that a width of a ridge portion and a difference between effective refractive index of a lower portion of the ridge portion and that of a side surface thereof for an oscillation wavelength are set to optimal values to thereby suppress the horizontal transverse mode from changing to the higher-order mode. Additionally, the thickness of a semiconductor layer positioned at the side surface of the ridge portion is adjusted to thereby control the difference between the effective refractive index of the lower portion of the ridge portion and that of the side surface thereof for the oscillation wavelength. Furthermore, the effective refractive index of one side surface of the ridge portion and that of the other side surface thereof are controlled to have the same value.

Meanwhile, there is proposed a semiconductor laser that is structured such that a ridge-portion inner angle of a second side surface of a ridge portion to a surface of an active layer is larger than that of a first side surface of the ridge portion to the surface of the active layer. At the same time, the semiconductor laser device is structured such that a first effective refractive index of the first side surface of the ridge portion for an oscillation wavelength is higher than a second effective refractive index of the second side surface of the ridge portion for an oscillation wavelength.

### SUMMARY OF THE INVENTION

A first aspect of the present invention is a semiconductor laser device comprising: an active layer, a semiconductor layer formed on the active layer and having a wurtzite structure, wherein a principal surface of the active layer is substantially perpendicular to a (0001) surface of the semiconductor layer, a current path portion in the semiconductor layer extends along a crystal orientation substantially parallel to the (0001) surface of the semiconductor layer, and an inner angle of the principal surface to a first side surface is different from an inner angle of the principal surface to a second side surface, the first side surface is a side surface of the current path portion and the second side surface is opposite to the first side surface.

Furthermore, in the semiconductor laser device according to the first aspect, the semiconductor layer may be made of a nitride semiconductor, the first side surface may be an N-polarity surface, and the second side surface may be a Ga-polarity surface. Herein, the “N-polarity surface” includes a (000-1) N surface and a surface, which is inclined at an off angle from the (000-1) N surface. The “Ga-polarity surface” includes a (0001) Ga surface and a surface, which is inclined at an off angle from the (0001) Ga surface.

Moreover, in the semiconductor laser device according to the first aspect, the semiconductor layer may include a projective portion having the first side surface and the second side surface of the semiconductor layer.

Furthermore, in the semiconductor laser device according to the first aspect, the semiconductor layer includes two flat portions continuously formed both side of the projective portion, and thickness of the two flat portions are different from each other.

Moreover, in the semiconductor laser device according to the first aspect, the side surfaces of the active layer are formed on the same plane as those of the current path portion.

Moreover, in the semiconductor laser device according to the first aspect, the principal surface of the active layer may be substantially parallel to a (11-20) surface of the semiconductor layer, and have a cleavage surface, being parallel to a (1-100) surface of the semiconductor layer, as a cavity surface.

Furthermore, in the semiconductor laser device according to the first aspect, the active layer may be formed on a (11-20) surface of a substrate which is made of a semiconductor having a hexagonal structure.

Furthermore, in the semiconductor laser device according to the first aspect, the active layer has a multiple quantum well structure including well layers and barrier layers which are laminated, crystal field splitting energy of material that forms the well layers is negative.

Furthermore, in the semiconductor laser device according to the first aspect, the active layer is formed to have a single-layered structure, crystal field splitting energy of material that forms the active layer is negative.

Furthermore, in the semiconductor laser device according to the first aspect, the active layer has a multiple quantum well structure including well layers and barrier layers which are laminated, the well layers is made of AlGaN, Al composition of the well layer is 0.32 or more.

Furthermore, in the semiconductor laser device according to the first aspect, the active layer is formed to have a single-layered structure, the active layer is made of AlGaN, Al composition of the active layer is 0.32 or more.

Furthermore, in the semiconductor laser device according to the first aspect, a hole ground state in the active layer comprises mainly a C-band.

Furthermore, in the semiconductor laser device according to the first aspect, the active layer is formed to have a quantum dot structure or a quantum wire structure.

Furthermore, in the semiconductor laser device according to the first aspect, the active layer has a multiple quantum well structure including well layers and barrier layers which are laminated, in-plane tensile strain is applied to a well layer.

Furthermore, in the semiconductor laser device according to the first aspect, the active layer is formed to have a single-layered structure, in-plane tensile strain is applied to a well layer.

Furthermore, in the semiconductor laser device according to the first aspect, the semiconductor devise oscillates in the TM mode.

A second aspect of the present invention is a method for manufacturing a semiconductor laser device including an active layer and a semiconductor layer having a wurtzite structure formed on the active layer, the method comprising the steps of: forming the semiconductor layer on the active layer having a principal surface substantially perpendicular to a (0001) surface of the semiconductor layer; and forming, in the semiconductor layer, a current path portion extending along a crystal orientation substantially parallel to the (0001) surface of the semiconductor layer, wherein the current path portion forming step includes a step of forming a first side surface as a side surface of the current path portion and a second side surface opposite to the first side surface by anisotropic etching, while the first side surface and the second side surface having different surface orientations from each other.

### BRIEF DESCRIPTION OF THE DRAWINGS

FIG. 1 is a cross-sectional diagram illustrating a GaN semiconductor laser device structure according to a first embodiment of the present invention.

FIG. 2 is a specific diagram of an active layer of the GaN semiconductor laser device shown in FIG. 1.

FIG. 3 is a graph illustrating a width size of a ridge portion that enables to suppress occurrence of a higher-order horizontal transverse mode, according to the first embodiment of the present invention.

FIG. 4 is a graph illustrating a width size of a ridge portion that can suppress the occurrence of a higher-order horizontal transverse mode according to a comparative example.

FIG. 5 is a cross-sectional diagram explaining a manufacturing method of a GaN semiconductor laser device according to the first embodiment of the present invention (No. 1).

FIG. 6 is a cross-sectional diagram explaining the manufacturing method of a GaN semiconductor laser device according to the first embodiment of the present invention (No. 2).

FIG. 7 is a cross-sectional diagram explaining the manufacturing method of a GaN semiconductor laser device according to the first embodiment of the present invention (No. 3).

FIG. 8 is a cross-sectional diagram explaining the manufacturing method of a GaN semiconductor laser device according to the first embodiment of the present invention (No. 4).

FIG. 9 is a cross-sectional diagram explaining the manufacturing method of a GaN semiconductor laser device according to the first embodiment of the present invention (No. 5).

FIG. 10 is a cross-sectional diagram explaining the manufacturing method of a GaN semiconductor laser device according to the first embodiment of the present invention (No. 6).

FIG. 11 is a cross-sectional diagram illustrating a GaN semiconductor laser device structure according to a second embodiment of the present invention.

FIG. 12 is a cross-sectional diagram explaining a manufacturing method of a GaN semiconductor laser device according to the second embodiment of the present invention (No. 1).

FIG. 13 is a cross-sectional diagram explaining the manufacturing method of a GaN semiconductor laser device according to the second embodiment (No. 2).

FIG. 14 is a cross-sectional diagram explaining the manufacturing method of a GaN semiconductor laser device according to the second embodiment (No. 3).

FIG. 15 is a cross-sectional diagram explaining the manufacturing method of a GaN semiconductor laser device according to the second embodiment (No. 4).

FIG. 16 is a cross-sectional diagram explaining the manufacturing method of a GaN semiconductor laser device according to the second embodiment (No. 5).

FIG. 17 is a cross-sectional diagram illustrating a GaN semiconductor laser device structure according to a third embodiment of the present invention.

FIG. 18 is a cross-sectional diagram perpendicular to the GaN semiconductor laser device shown in FIG. 17:

FIG. 19 is a cross-sectional diagram explaining a manufacturing method of a GaN semiconductor laser device according to the third embodiment (No. 1).

FIG. 20 is a cross-sectional diagram explaining the manufacturing method of a GaN semiconductor laser device according to the third embodiment (No. 2).

FIG. 21 is a cross-sectional diagram illustrating a GaN semiconductor laser device structure according to a fourth embodiment of the present invention.

FIG. 22 is a specific diagram of an active layer of a GaN semiconductor laser device according to a fifth embodiment of the present invention.

FIG. 23 is a plane diagram illustrating quantum dots structure of an active layer according to the fifth embodiment.

FIG. 24 is a cross-sectional diagram illustrating a GaN semiconductor laser device structure according to a sixth embodiment of the present invention.

FIG. 25 is a cross-sectional diagram explaining a manufacturing method of a GaN semiconductor laser device according to the sixth embodiment.

### DESCRIPTION OF THE PREFERRED EMBODIMENTS

The following will explain embodiments of the present invention with reference to drawings. In the following description of drawings, the same or similar reference numerals are added to the same or similar portions. However, it should be noted that diagrams are schematic, and a ratio of each size, for example, is different from the actual ratio. Accordingly, the specific size should be judged in consideration of the following explanation. Meanwhile, as a matter of course, there are included descriptions having different relationships and ratios in size among the drawings.

### First Embodiment

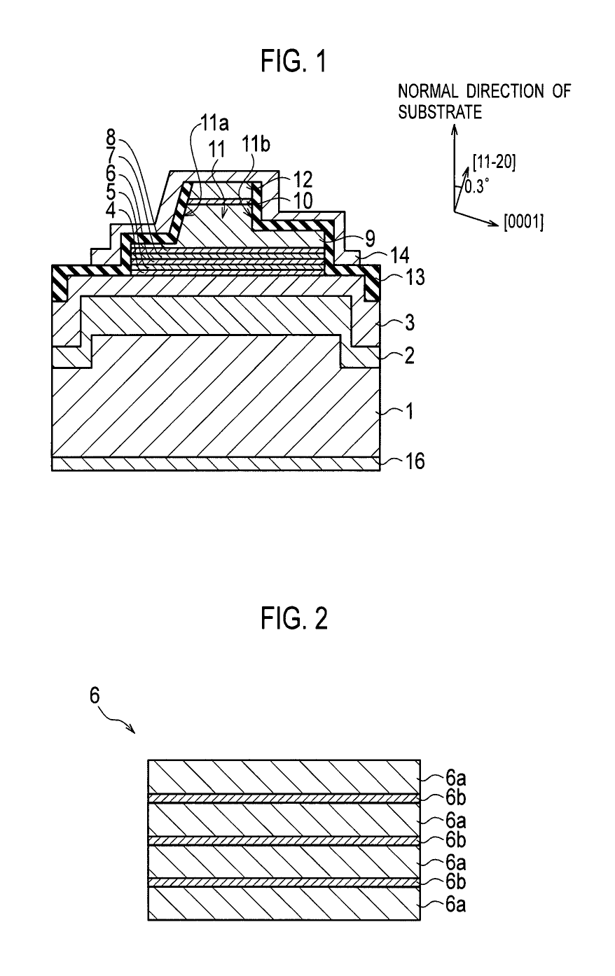

FIG. 1 is a cross-sectional diagram illustrating a GaN semiconductor laser device structure according to a first embodiment of the present invention, and FIG. 2 is a specific diagram of an active layer of the GaN semiconductor laser device according to the first embodiment shown in FIG. 1. First, the GaN semiconductor laser device structure according to the first embodiment will be described with reference to FIG. 1 and FIG. 2. An oscillation wavelength of the GaN semiconductor laser device according to the first embodiment is about 410 nm.

In the first embodiment, as illustrated in FIG. 1, an n-type layer 2 is formed on Si-doped n-type GaN (11-20) misoriented substrate 1 having a thickness of about 100 μm and a carrier concentration of about 5×10¹⁸ cm⁻³. The n-type GaN (11-20) misoriented substrate 1 is misoriented by 0.3° from (11-20) surface toward a [000-1] direction. Meanwhile, the n-type layer 2 is made of Si-doped n-type GaN having a thickness of about 100 nm and a doping amount of about 5×10¹⁸ cm⁻³. Furthermore, grooves having a depth of about 0.5 μm extending in the [1-100] direction and a width of about 20 μm, are formed on the n-type GaN (11-20) misoriented substrate 1. Each groove is positioned at both end of the semiconductor laser device. On the n-type layer 2, an n-type cladding layer 3 is formed. The n-type cladding layer 3 is made of a Si-doped n-type Al_{0.7}Ga_{0.93}N having a thickness of about 400 nm, a doping amount of about 5×10¹⁸ cm⁻³ and a carrier concentration of about 5×10¹⁸ cm⁻³.

On the n-type cladding layer 3, an n-type carrier blocking layer 4 is formed. The n-type carrier blocking layer 4 is made of a Si-doped n-type Al_{0.16}Ga_{0.84}N, having a thickness of about 5 nm, a doping amount of about 5×10¹⁸ cm⁻³ and a carrier concentration of about 5×10¹⁸ cm⁻³. On the n-type carrier blocking layer 4, an n-type optical guide layer 5 is formed. The n-type optical guide layer 5 is made of Si-doped n-type GaN having a thickness of about 100 nm, a doping amount of about 5×10¹⁸ cm⁻³ and a carrier concentration of about 5×10¹⁸ cm⁻³.

On the n-type optical guide layer 5, an active layer 6 is formed. As illustrated in FIG. 2, the active layer 6 has a multiple quantum well (MQW) structure in which four barrier layers 6a and three well layers 6b are stacked alternately. The barrier layer Ga is made of undoped In_{0.02}Ga_{0.98}N having a thickness of about 20 nm. The well layer 6b is made of undoped In_{0.15}Ga_{0.85}N having a thickness of about 3 nm.

Furthermore, as illustrated in FIG. 1, on the active layer 6, a p-type optical guide layer 7 is formed. The p-type optical guide layer 7 is made of Mg-doped p-type GaN having a thickness of about 100 nm, a doping amount of about 4×10¹⁹ cm⁻³ and a carrier concentration of about 5×10¹⁷ cm⁻³. On the p-type guide layer 7, a p-type cap layer 8 is formed. The cap layer 8 is made of an Mg-doped p-type Al_{0.16}Ga_{0.84}N having a thickness of about 20 nm, a doping amount of about 4×10¹⁹ cm⁻³ and a carrier concentration of about 5×10¹⁷ cm⁻³.

On the p-type cap layer 8, a p-type cladding layer 9 is formed. The p-type cladding layer 9 is made of an Mg-doped p-type Al_{0.07}Ga_{0.93}N, and has a projective portion and flat portions continuous to both sides of the projective portion. The Mg-doped p-type Al_{0.07}Ga_{0.98}N has a doping amount of about 4×10¹⁹ cm⁻³ and a carrier concentration of about 5×10¹⁷ cm⁻³.

The thickness of the flat portions of the p-type cladding layer 9 differs at both sides of the projective portion. Specifically, the thickness of the flat portion on the left side of the projective portion is about 10 nm, and a right side thereof is about 80 nm in the cross section shown in FIG. 1. Moreover, a height from the upper surface of the p-type cladding layer 9 to the lower surface of the flat portions is about 320 nm, and a width of the projective portion is 1.75 μm.

On the projective portion of the p-type cladding layer 9, a p-type contact layer 10 is formed. The p-type contact layer 10 is made of Mg-doped p-type In_{0.02}Ga_{0.98}N having a thickness of about 10 nm, a doping amount of about 4×10¹⁹ cm⁻³ and a carrier concentration of about 5×10¹⁷ cm⁻³.

A ridge portion 11 is formed of the p-type contact layer 10 and the projective portion of the p-type cladding layer 9. The ridge portion 11 has one side surface 11a and other side surface 11b opposite to the side surface 11a. Furthermore, the ridge portion 11 has a width of 1.75 μm at its lower portion, and is formed in a shape extending in the [1-100] direction. Note that a p-type semiconductor layer is formed of the p-type optical guide layer 7, the p-type cap layer 8, the p-type cladding layer 9, and the p-type contact layer 10. This p-type semiconductor layer is one example of a “semiconductor layer” of the present invention. Moreover, the side surfaces 11a and 11b are examples of a “first side surface” and a “second side surface” of the present invention, respectively. Furthermore, the ridge portion 11 is one example of a “current path portion” of the present invention.

Furthermore, an inner angle of the side surface 11a as a side surface of the current path portion to a principal surface of the active layer 6 is different from that of the side surface 11b to the principal surface of the active layer 6. Herein, in the first embodiment, the side surface 11a has a surface orientation inclined at 25° to 30° from a (000-1) N surface. On the other hand, the side surface 11b has a surface orientation inclined at 5° or less from a (0001) Ga surface. In this respect, an inclined angle of the side surface 11a to the principal surface of the active layer 6 is made smaller than that of the side surface 11b to the principal surface of the active layer 6, thereby allowing an effective refractive index of the active layer 6 in the vicinity of the lower portion of the side surface 11a to be made smaller than that in the vicinity of the side surface 11b.

Moreover, on the p-type contact layer 10 that forms the ridge portion 11, a p-side ohmic electrode 12 is formed. The p-side ohmic electrode 12 is made of a Pt layer having a thickness of about 5 nm, a Pd layer having a thickness of about 100 nm, and an Au layer having a thickness of about 150 nm, in an order from the lower layer to the upper layer. A current confinement layer 13 is formed on the entire upper surface except that of the p-side electrode 12. The current confinement layer 13 is made of a SiO₂ film (insulating film) having a thickness of about 250 nm. In a predetermined region on the current confinement layer 13, a p-side pad electrode 14 is formed. The p-side pad electrode 14 is made of a Ti layer having a thickness of about 100 nm, a Pd layer having a thickness of about 100 nm and an Au layer having a thickness of about 3 μm, in the order from the lower layer to the upper layer in such a way to come into contact with the upper surface of the p-side ohmic electrode 12.

Moreover, on the back surface of the n-type GaN substrate 1, an n-side electrode 16 is formed. The n-side electrode 16 is made of an Al layer having a thickness of about 10 nm, a Pt layer having a thickness of about 20 nm and an Au layer having a thickness of about 300 nm in the order from the back surface of the n-type GaN substrate 1.

Furthermore, a cavity surface is formed on each of both end portions of the ridge portion. The cavity surface is made of a {1-100} surface cleavage plane. A dielectric multilayer film with a reflectivity of 5% is formed on the cavity surface on a laser beam emission surface side, and a dielectric multilayer film with a reflectivity of 95% is formed on an opposite side of the cavity surface.

An explanation will be next given of a calculated result of the width size of the ridge portion that enables to suppress the occurrence of higher-order horizontal transverse mode with respect to light having an oscillation wavelength of 410 nm when the effective refractive index of one side surface of the ridge portion is different from that of the other side surface thereof. Additionally, as a comparative example, a calculation is made of the width size of the ridge portion that enables to suppress the occurrence of higher-order horizontal transverse mode with respect to light having an oscillation wavelength of 410 nm when the effective refractive index of the one side surface of the ridge portion is the same as that of the other side surface thereof.

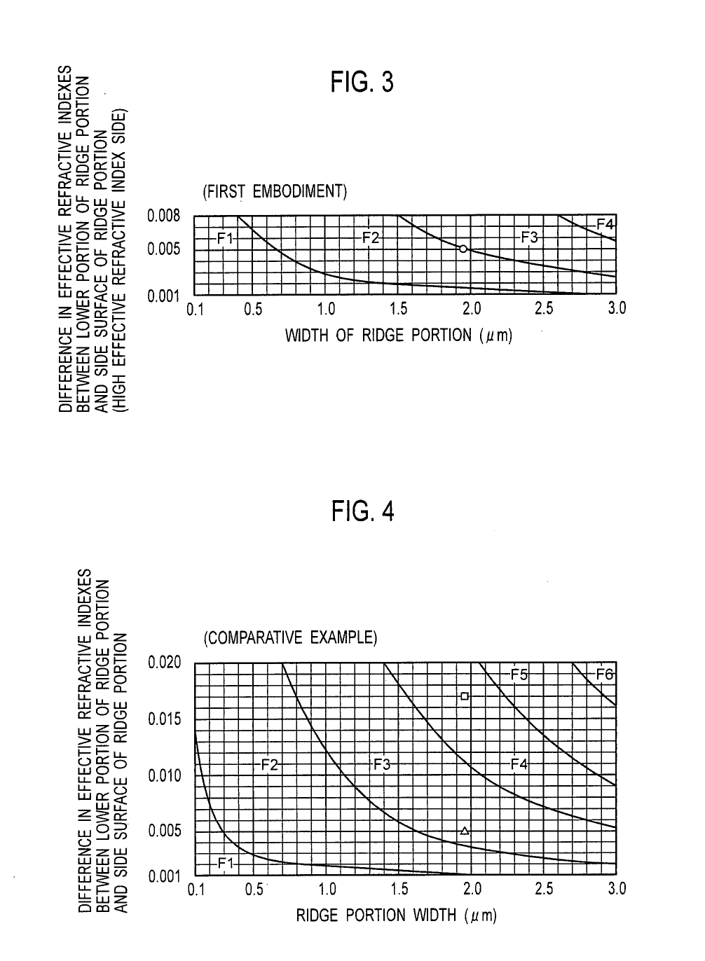

FIG. 3 is a graph illustrating the width size of the ridge portion that enables to suppress the occurrence of higher-order horizontal transverse mode when the effective refractive index of the one side surface of the ridge portion is different from that of the other side surface thereof. FIG. 4 is a graph illustrating the width size of the ridge portion that enables to suppress the occurrence of higher-order horizontal transverse mode when the effective refractive index of one side surface of the ridge portion is the same as that of the other side surface thereof (comparative example). Note that, FIG. 3 is a graph showing a case where a difference in effective refractive index between one side surface of the ridge portion and the other side surface thereof is 0.012 with respect to light having an oscillation wavelength of 410 nm. Moreover, FIG. 4 is a graph showing a case where the effective refractive index of one side surface of the ridge portion is the same as that of the other side surface thereof. Furthermore, regions F1, F2, F3, and F4 in FIGS. 3 and 4 indicate a cut-off region, a region where only a zeroth-order mode (fundamental mode) exists, a region where modes up to a first-order mode exist and a region where modes up to a second-order mode exist, respectively. Moreover, regions F5 and F6 in FIG. 4 indicate a region where modes up to a third-order mode exist and a region where modes up to a fourth-order mode exist, respectively. The high-order mode herein indicates the first-order mode or higher. Moreover, in FIGS. 3 and 4, the width size of the ridge portion is plotted in abscissa, and the difference in effective refractive index between the lower portion of the ridge portion and the side surface thereof is plotted in ordinate. However, it should be noted that the side surface of the ridge portion in FIG. 3 is a side having a high effective refractive index.

First, it was shown, with reference to FIG. 3, that only a zero-order horizontal transverse mode (F2 region) existed (circle in FIG. 3) when the difference in effective refractive index between the lower portion of the ridge portion and the side surface of the ridge portion with a higher effective refractive index was 0.005, and when the width of the ridge portion was 1.95 μm or less in the case where the difference in effective refractive index between one side surface of the ridge portion and the other side surface thereof was 0.012. In this case, the difference in effective refractive index between the lower portion of the ridge portion and the side surface of the ridge portion with a lower effective refractive index is 0.017. Note that, in the first embodiment, the difference in effective refractive index between one surface side of the ridge portion and the other side surface thereof must to be set smaller than 0.012, and the width of the ridge portion must to be set smaller than 1.95 μm.

Meanwhile, it was shown, with reference to FIG. 4, that horizontal transverse modes up to a first-order mode (F3 region) existed (triangle in FIG. 4) when the difference in effective refractive index between the lower portion of the ridge portion and the side surface thereof was 0.005, and when the width of the ridge portion was 1.95 μm in the case where one side surface of the ridge portion and the other side surface had the same effective refractive index (comparative example). In this case, the width of the ridge portion must be 1.64 μm or less in order that only the zero-order horizontal transverse mode (F2 region) exists. Furthermore, it was shown that horizontal transverse modes up to second-order mode (F4 region) existed (square in FIG. 4) when the difference in effective refractive index between the lower portion of the ridge portion and the side surface thereof was 0.017, and when the width of the ridge portion was 1.95 μm. In this case, the width of the ridge portion must be 0.79 μm or less in order that only the zero-order horizontal transverse node (F2 region) exists.

Next, calculation was made of a beam horizontal-divergent angle of a GaN semiconductor laser device where the difference in effective refractive index between the lower portion of the ridge portion and the side surface of the ridge portion with a higher effective refractive index was 0.005, and where the width of the ridge portion was 1.95 μm in the case where the difference in effective refractive index between one side surface of the ridge portion and the other side surface thereof was 0.012. As a result, the beam horizontal-divergent angle was about 8.8°. Meanwhile, in the GaN semiconductor laser device where one side surface of the ridge portion and the other side surface had the same effective refractive index (comparative example), the beam horizontal-divergent angle was about 7.7° when the difference in effective refractive index between the lower portion of the ridge portion and the side surface thereof was 0.005. This makes it possible to increase the beam horizontal-divergent angle while suppressing the occurrence of higher-order horizontal transverse mode.

In the first embodiment, the inclined angle of the side surface 11a to the principal surface of the active layer is made smaller than that of the side surface 11b to the principal surface of the active layer, whereby the effective refractive index of the active layer in the vicinity of the lower portion of the side surface 11a is made smaller than that in the vicinity of the lower portion of the side surface 11b. It is, therefore, possible to increase the upper limit size of the width of the ridge portion 11 that enables to suppress the occurrence of higher-order horizontal transverse mode as compared with the case where the side surface 11a of the ridge portion 11 and the side surface 11b thereof have the same effective refractive index. This makes it possible to increase the width of the ridge portion 11 while suppressing the occurrence of a kink caused by occurrence of the higher-order horizontal transverse mode. In this case, it is possible to increase a contact area between the p-type contact layer 10 that forms the ridge portion 11 and the p-side ohmic electrode 12 formed on the ridge portion 11, and therefore contact resistance between the p-type contact layer 10 and the p-side ohmic electrode 12 can be reduced. This makes it possible to reduce an operating voltage of the device while suppressing the occurrence of a kink. As a result, it is possible to reduce the operating voltage of the device while obtaining a good laser characteristic at the time of a high output operation. In order to obtain the current path portion extending in the crystal orientation which is substantially parallel to the (0001) surface of the semiconductor layer and the principal surface of the active layer 6 which is substantially perpendicular to the (0001) surface of the semiconductor layer as mentioned above, the crystal orientation to which the current path portion extends may be set to a [K, −H, H−K, 0] direction, and the principal surface of the active layer 6 may be set to a (H, K, −H−K, 0) surface in general. Moreover, in order to set the principal surface of the active layer 6 to the (H, K, −H−K, 0) surface, the surface orientation of a substrate 1 may be set to the (H, K, −H−K, 0) surface.

Furthermore, the semiconductor layer is made of a nitride semiconductor. The first side surface thereof is an N-polarity surface. The second side surface thereof is a Ga-polarity surface. Herein, the “N-polarity surface” includes a (000-1) N surface and a surface misoriented from the (000-1) N surface. The “Ga-polarity surface” includes a (0001) Ga surface and a surface misoriented from the (0001) Ga surface.

According to this semiconductor laser device, the first side surface and the second side surface have the N-polarity surface and the Ga-polarity surface, respectively. It is, therefore, possible to easily obtain the first side surface and the second side surface, each having a different angle from that of the other, using anisotropic etching.

Moreover, it is possible to easily manufacture the structure in which the current path portion extends along the crystal orientation which is substantially parallel to the (0001) surface of the semiconductor layer, and in which the principal surface of the active layer 6 is substantially perpendicular to the (0001) surface of the semiconductor layer, thereby the inner angle of the first side surface to the principal surface and that of the second side surface to the principal surface are different from each other, namely, the structure in which the first side surface and the second side surface have different surface orientations.

Moreover, the semiconductor layer includes a projective portion having the first side surface and the second side surface of the semiconductor layer.

According to the semiconductor laser device, it is possible to reduce a difference between effective refractive index of the active layer 6 of the lower portion of the projective portion and the lower portions of the side surfaces of the projective portion for an oscillation wavelength As a result, an effect of suppressing generation of the higher-order horizontal transverse mode is further increased.

Furthermore, thickness of the two flat portions is different from each other.

According to the semiconductor laser device, one of two flat portions continuous to either side of the projective portion may have a thickness different from that of the other one of the two flat portions, and therefore it is possible to increase the difference between effective refractive index of the first side surface of the active layer 6 and the second side surface thereof for an oscillation wavelength. As a result, an effect of suppressing generation of the higher-order horizontal transverse mode is further increased.

Moreover, the principal surface of the active layer 6 is substantially parallel to a (11-20) surface of the semiconductor layer, and has a cleavage surface, being parallel to a (1-100) surface of the semiconductor layer, as a cavity surface. According to the semiconductor laser device, a flat cavity surface can be easily formed by cleavage while a piezoelectric field can be suppressed from being applied to the active layer 6. As a result, it is possible to further reduce the operating voltage of the device.

Furthermore, a substrate 1 is made of a semiconductor having a hexagonal structure, and the active layer 6 is formed on the (11-20) surface of the substrate 1. Here, the (11-20) surface of the substrate 1 may be misoriented. Using such a semiconductor substrate 1 allows the semiconductor laser device of the first embodiment to be easily formed.

Moreover, in this embodiment, since the grooves are formed on each side of the semiconductor laser device, a lattice constant of AlGaN substrate is smaller than that of the GaN substrate, and therefore it is possible to prevent a crack from generating on the semiconductor layer. Particularly, a lattice constant of an a-axis of AlN is about 98% of that of GaN, and a lattice constant of a c-axis of AlN is about 96% of that of GaN. Thus distortion in a c-axial direction ([0001] direction) is large, and accordingly a crack is easily generated in the c-axial direction. In this embodiment, since the grooves extending in a [1-100] direction are formed on the substrate, distortion in the c-axial direction is relaxed at the groove portion, and therefore it is possible to suppress crack generation in the c-axial direction.

Herein, the grooves are formed to have a depth larger than the thickness of the n-type cladding layer or that of p-type cladding layer. By setting the depth of groove in this way, an effect of preventing the crack generation is increased. The depth of groove is preferably 0.4 μm to 50 μm. Moreover, the width of groove is formed to be larger than the total thickness of the layers formed on the substrate. By setting the width of groove in this way, the grooves are not buried at the time of crystal growing. Thereby an effect of preventing crack generation is increased. The width of groove is preferably 2 μm to 300 μm.

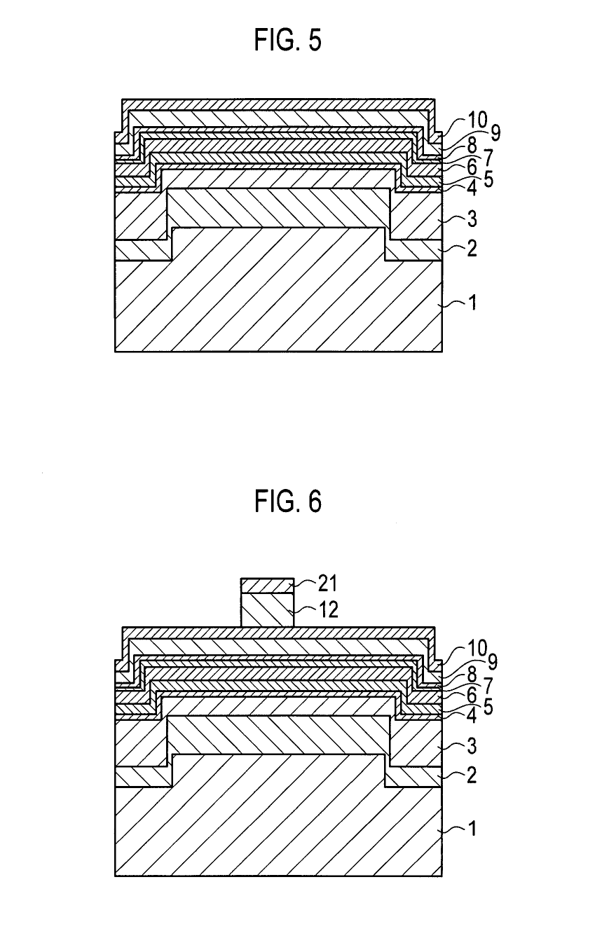

An explanation will be next given of a GaN semiconductor laser device manufacturing method according to the first embodiment with reference to FIGS. 5 to 10.

First, as illustrated in FIG. 5, on an n-type GaN (11-20) misoriented substrate 1, grooves having a depth of about 0.5 μm extending in a [1-100] direction and a width of about 40 μm is formed at an interval of about 400 μm.

Next, an n-type layer 2, an n-type cladding layer 3, and an n-type carrier blocking layer 4 are grown on the n-type GaN substrate 1 at 1100° C. using a metal organic vapor phase epitaxy (MOVPE) method. After that, an n-type optical guide layer 5, an active layer 6, a p-type optical guide layer 7, and a p-type cap layer 8 are grown on the n-type carrier blocking layer 4 at 800° C. Subsequently, a p-type cladding layer 9 having a thickness of about 400 nm is grown on the p-type cap layer 8 at 1100° C. Then, a p-type contact layer 10 is grown on the p-type cladding layer 9 at 800° C.

Thereafter, annealing is performed in a nitrogen gas atmosphere under a temperature condition of about 850° C.

Next, a p-side ohmic electrode 12 is formed on the p-type contact layer 10 using an electron-beam evaporation method. After that, on the p-side ohmic electrode 12, a SiO₂ film 21 having a thickness of about 250 nm is formed. Moreover, as illustrated in FIG. 6, the p-side ohmic electrode 12 and the SiO₂ film 21 are patterned, to form the p-side ohmic electrode 12 and SiO₂ film 21 in a stripe shape extending in a [1-100] direction and having a width of 1.75 μm.

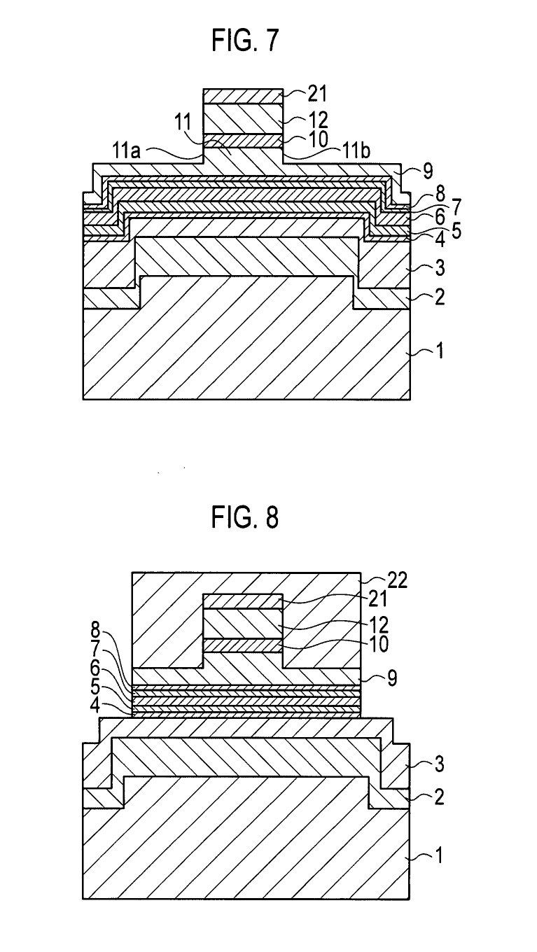

Next, as illustrated in FIG. 7, the SiO₂ film 21 is used as a mask to etch portions of the layers into a depth from the upper surface of the p-type contact layer 10 to the midpoint of the p-type cladding layer 9 (depth of about 320 nm from the upper surface of the p-type cladding layer 9) by a dry etching technique using Cl₂ gas. At this time, a substrate temperature is maintained at about 200° C. As a result, a stripe-shaped ridge portion 11 is formed, which is made of the p-type contact layer 10 and a projective portion of the p-type cladding layer 9, and which has a width of about 1.75 μm at its lower portion. Herein, a side surface 11a serves as a (000-1) N surface, and a side surface 11b serves as a (0001) Ga surface, having a surface orientation substantially perpendicular to a principal surface of the active layer.

Next, a resist 22 is formed on flat portions of the p-type cladding layer 9 to cover the SiO₂ film 21, the p-side ohmic electrode 12 and the ridge portion 11. Then, the resist 22 is used as a mask to etch portions from the upper surface of the flat portion of the p-type cladding layer 9 to the n-type carrier blocking layer 4. As a result, as illustrated in FIG. 8, the p-type cladding layer 9, the p-type cap layer 8, the p-type optical guide layer 7, the active layer 6, the n-type optical guide layer 5 and the n-type carrier blocking layer 4 are removed. After that, the resist 22 is removed therefrom.

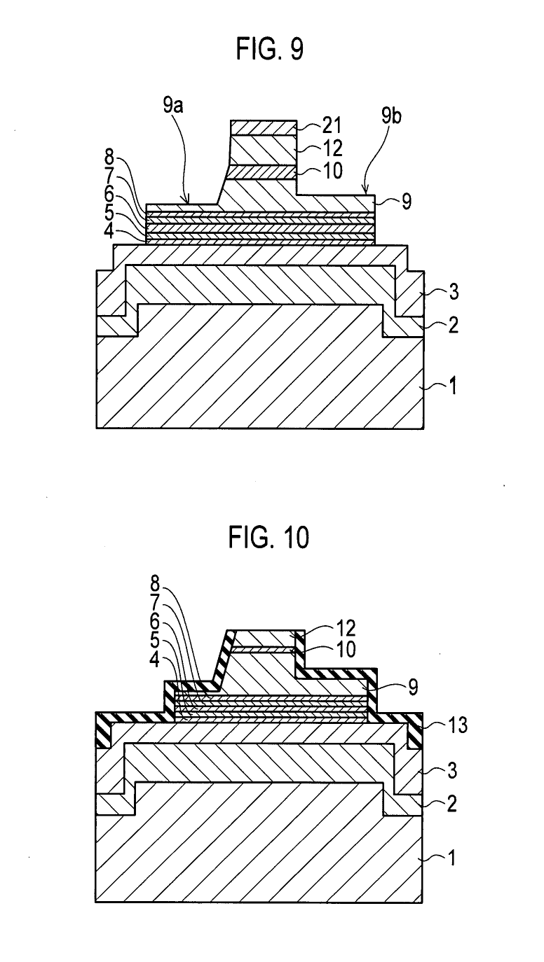

Next, as illustrated in FIG. 9, the ridge side surfaces are etched using an aqua solution of KOH and so on. At this time, since the side surface 11a has the (000-1) N surface, it is easily etched. The side surface 11b has the chemically stable (0001) Ga surface, and therefore is little etched. As a result, the side surface 11a has a surface orientation inclined at 25° to 30° from the (000-1) N surface, while the side surface 11b has a surface orientation inclined at 5° or less from the (0001) Ga surface. Note that the etching in this case is performed preferably based on condition of a supply limitation. Furthermore, regarding the flat portion in the vicinity of the ridge, the flat portion 9a adjacent to the (000-1) surface side of the ridge is easily etched. As a result, the thickness of the flat portion 9a is about 10 nm on the left side of the projective portion. Herein, two side surfaces of the p-side semiconductor layer are formed to have different surface orientations from each other, thereby making it possible to easily set inclined angles of two side surfaces of the p-side semiconductor layer to be different from each other. From this reason, the flat portions 9a and 9b of the p-side semiconductor layer are easily formed to have different thicknesses at right and left portions of the ridge.

Next, a current confinement layer 13, made of a SiO₂ film with a thickness of about 250 nm, is formed to cover the entire surface of the layers including both side surfaces 11a and 11b of the ridge portion 11 using a plasma CVD method. After that, a resist is formed on a region except for the region corresponding to the ridge portion 11 on the current confinement layer 13. Next, the resist is used as a mask to etch the current confinement layer 13 positioned on the upper surface of the p-side ohmic electrode 12. Thus, a state as shown in FIG. 10 is obtained. After that, the resist is removed therefrom.

Next, a p-side pad electrode 14 is formed on a predetermined region of the current confinement 13 using a vacuum deposition method. Thus, the p-side pad electrode 14 comes in contact with the upper surface of the p-side ohmic electrode 12. Finally, as illustrated in FIG. 1, an n-side electrode 16 is formed on the back surface of the n-type GaN substrate 1 using the vacuum deposition method.

Then, the resultant is cleaved along a {1-100} surface, and the obtained cleavage plane is used as a cavity surface. A dielectric multilayer film is formed thereon. After that, the resultant is separated at the central portion of the groove with a width of 40 μm. As a result, the GaN semiconductor laser device according to the first embodiment is formed.

As mentioned above, according to the first embodiment, it is possible to manufacture the semiconductor laser device capable of easily adjusting angles of the side surfaces of the ridge portion to be a left-right asymmetry and reducing an operating voltage of the device while suppressing the occurrence of a kink.

In order to form the first side surface as a side surface of the current path portion and the second side surface thereof opposite to the first side surface, each having a different orientation from that of the other, the first side surface as a side surface of the current path portion and the second side surface thereof opposite to the first side surface are formed by isotropic etching, and thereafter the first side surface and the second side surface may be etched using an anisotropic etchant such as aqueous alkaline solution. In this case, the first side surface and the second side surface are etched by wet etching, thereby an effect of reducing crystal defects on both side surfaces can be expected.

### Second Embodiment

An oscillation wavelength of a GaN semiconductor laser device according to a second embodiment is about 530 nm.

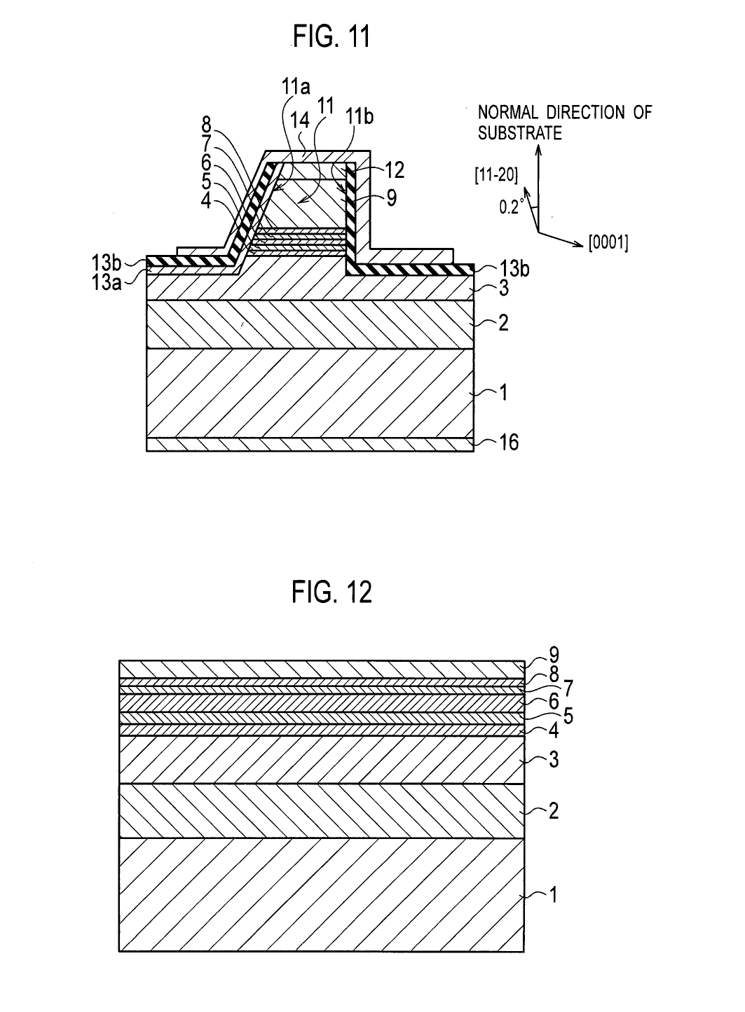

In the second embodiment, as illustrated in FIG. 11, an n-type layer 2 is formed on a Si-doped n-type GaN (11-20) misoriented substrate 1 having a thickness of about 100 μm and a carrier concentration of about 5×10¹⁸ cm⁻³. The n-type GaN (11-20) misoriented substrate is misoriented by 0.2° from (11-20) surface toward a [000-1] direction. Meanwhile, the n-type layer 2 is made of Si-doped n-type GaN having a thickness of about 100 nm and a doping amount of about 5×10¹⁸ cm⁻³. On the n-type layer 2, an n-type cladding layer 3 is formed. The n-type cladding layer 3 is made of a Si-doped n-type Al_{0.01}Ga_{0.99}N, and has a projective portion and flat portions continuous to both sides of the projective portion, a doping amount of about 5×10¹⁸ cm⁻³ and a carrier concentration of about 5×10¹⁸ cm⁻³. The thickness of the flat portions of the n-type cladding layer 3 is about 200 nm. Furthermore, a height from the upper surface of the n-type cladding layer 3 to the flat portions is about 200 nm, and is formed in a shape extending in a [1-100] direction.

On the n-type cladding layer 3, an n-type carrier blocking layer 4 is formed. The n-type carrier blocking layer 4 is made of Si-doped n-type Al_{0.1}Ga_{0.9}N having a thickness of about 6 mm, a doping amount of about 5×10¹⁸ cm⁻³ and a carrier concentration of about 5×10¹⁸ cm⁻³. On the n-type carrier blocking layer 4, an n-type optical guide layer 5 is formed. The n-type optical guide layer 5 is made of Si-doped n-type In_{0.1}Ga_{0.9}N having a thickness of about 100 nm, a doping amount of about 5×10¹⁸ cm⁻³ and a carrier concentration of about 5×10¹⁸ cm⁻³.

On the n-type optical guide layer 5, an active layer 6 is formed. The active layer 6 has the same stacked structure as that of the first embodiment shown in FIG. 2 though the composition is different from that shown in FIG. 2. Specifically, the active layer 6 has an MQW structure in which four barrier layers 6a and three well layers 6b are stacked alternately. The barrier layer 6a is made of undoped InGaN having a thickness of about 20 nm. The well layer 6b is made of undoped InGaN having a thickness of about 3 nm. The width of the active layer 6 is 1.2 μm.

Furthermore, as illustrated in FIG. 11, on the active layer 6, a p-type optical guide layer 7 is formed. The p-type optical guide layer 7 is made of Mg-doped p-type In_{0.1}Ga_{0.9}N having a thickness of about 100 nm, a doping amount of about 4×10¹⁹ cm⁻³ and a carrier concentration of about 5×10¹⁷ cm⁻³. On the p-type optical guide layer 7, a p-type cap layer 8 is formed. The p-type cap layer 8 is made of Mg-doped p-type Al_{0.1}Ga_{0.9}N having a thickness of about 20 nm, a doping amount of about 4×10¹⁹ cm⁻³ and a carrier concentration of about 5×10¹⁷ cm⁻³.

On the p-type cap layer 8, a p-type cladding layer 9 is formed. The p-type cladding layer 9 is made of Mg-doped p-type Al_{0.01}Ga_{0.99}N having a thickness of about 400 nm, a doping amount of about 4×10¹⁹ cm⁻³ and a carrier concentration of about 5×10¹⁷ cm⁻³. The p-type cladding layer 9 also serves as a contact layer. Note that, each of the p-type optical guide layer 7, the p-type cap layer 8, and the p-type cladding layer 9 is one example of a “semiconductor layer” of the present invention. Moreover, the side surfaces 11a and 11b of the p-type optical guide layer 7, the p-type cap layer 8, and the p-type cladding layer 9 are examples of a “first side surface” and a “second side surface” of the present invention, respectively.

Furthermore, one side surface 3a of the projective portion of the n-type cladding layer 3 and one side surface 6a of the active layer 6 are arranged on the same plane as the side surface 11a. The other side surface 3b of the projective portion of the n-type cladding layer 3 and the other side surface 6b of the active layer 6 are arranged on the same as the side surface 11b (see FIG. 14).

Herein, in the second embodiment, the side surface 3a, the side surface 6a and the side surface 11a have surface orientations inclined at 25° to 30° from a (000-1) N surface. On the other hand, the side surface 3b, the side surface 6b and the side surface 11b have surface orientations inclined at 5° or less from a (0001) Ga surface. In this respect, an inclined angle of each of the side surface 6a and the side surface 11a to the principal surface of the active layer 6 is made smaller than that of each of the side surface 6b and the side surface 11b to the principal surface of the active layer 6, thereby allowing an effective refractive index in the vicinity of one side surface of the active layer 6 to be made smaller than that of the other side surface of the active layer 6.

Furthermore, on the p-type cladding layer 9, a p-side ohmic electrode 12 is formed, the electrode 12 having the same structure as that in the first embodiment. On the flat portion of the n-type cladding layer 3 in the vicinity of the side surface 3a, the side surface 3a, the side surface 6a and the side surface 11a, a current confinement layer 13a is formed. The current confinement layer 13a is made of a SiO₂ film having a thickness of about 250 nm. On the flat portion of the n-type cladding layer 3 in the vicinity of the side surface 3b, the side surface 3b, the side surface 6b and the side surface 11b, a current confinement layer 13b is formed. The current confinement layer 13b is made of an Nb₂O₅ film (insulating film) having a thickness of about 250 nm. On predetermined regions of the current confinement layers 13a and 13b, a p-side pad electrode 14 is formed in such a way to come into contact with the upper surface of the p-side ohmic electrode 12. The p-side pad electrode 14 has the same structure as that of the first embodiment.

Moreover, on the back surface of the n-type GaN substrate 1, an n-side electrode 16 is formed, having the same structure as that of the first embodiment.

Furthermore, a cavity surface is formed on each of both end portions of the ridge portion. The cavity surface is made of a {1-100} surface cleavage plane. A dielectric multilayer film is formed on the cavity surface.

In the second embodiment, the inclined angle of each of the side surface 6a and the side surface 11b to the principal surface of the active layer 6 is made smaller than that of each of the side surface 6b and the side surface 11b to the principal surface of the active layer 6, whereby the effective refractive index of the active layer 6 in the vicinity of the side surface 6a is made smaller than that of the active layer 6 in the vicinity of the side surface 6b. It is, therefore, possible to increase the upper limit size of the width of the active layer 6 that enables to suppress the occurrence of higher-order horizontal transverse mode as compared with the case where the side surface 6a and the side surface 6b have the same effective refractive index. This makes it possible to increase the width of the active layer while suppressing the occurrence of a kink caused by the occurrence of higher-order horizontal transverse mode. In this case, it is possible to increase a contact area between the p-type cladding layer 9 and the p-side ohmic electrode 12, and therefore contact resistance between the p-type cladding layer 9 and the p-side ohmic electrode 12 can be reduced. This makes it possible to reduce an operating voltage of the device while suppressing the occurrence of a kink. As a result, it is possible to reduce the operating voltage of the device while obtaining a good laser characteristic at the time of a high output operation.

Moreover, the side surfaces of the active layer 6 are formed on the same plane as those of the current path portion.

According to the semiconductor laser device, the effective refractive index of the side surfaces of the active layer 6 for an oscillation wavelength is considerably affected by an refractive index of each of layers except for the active layer 6, that is, layers placed on the side surfaces of the active layer 6 (one side may be an air layer), and therefore it is possible to increase a difference between the effective refractive index of the first side surface of the active layer 6 and of the second side surface thereof for an oscillation wavelength. As a result, an effect of suppressing generation of the higher-order horizontal transverse mode is further increased.

An explanation will be next given of a GaN semiconductor laser device manufacturing method according to the second embodiment with reference to FIGS. 12 to 16.

First, as illustrated in FIG. 12, an n-type layer 2, an n-type cladding layer 3, and an n-type carrier blocking layer 4 are grown on an n-type GaN substrate 1 at 1100° C. using a MOVPE method. After that, an n-type optical guide layer 5, an active layer 6, a p-type optical guide layer 7, and a p-type cap layer 8 are grown on the n-type carrier blocking layer 4 at 800° C. Subsequently, a p-type cladding layer 9 having a thickness of about 400 nm is grown on the p-type cap layer 8 at 950° C.

After that, annealing is performed in a nitrogen gas atmosphere under a temperature condition of about 850° C.

Next, a p-side ohmic electrode 12 is formed on the p-type cladding layer 9 using an electron-beam evaporation method. After that, a SiO₂ film 21 having a thickness of about 250 nm is formed on the p-side ohmic electrode 12. Then, the p-side ohmic electrode 12 and the SiO₂ film 21 are patterned to form the p-side ohmic electrode 12 and SiO₂ film 21 in a stripe shape extending in a [1-100] direction and having a width of 1.3 μm.

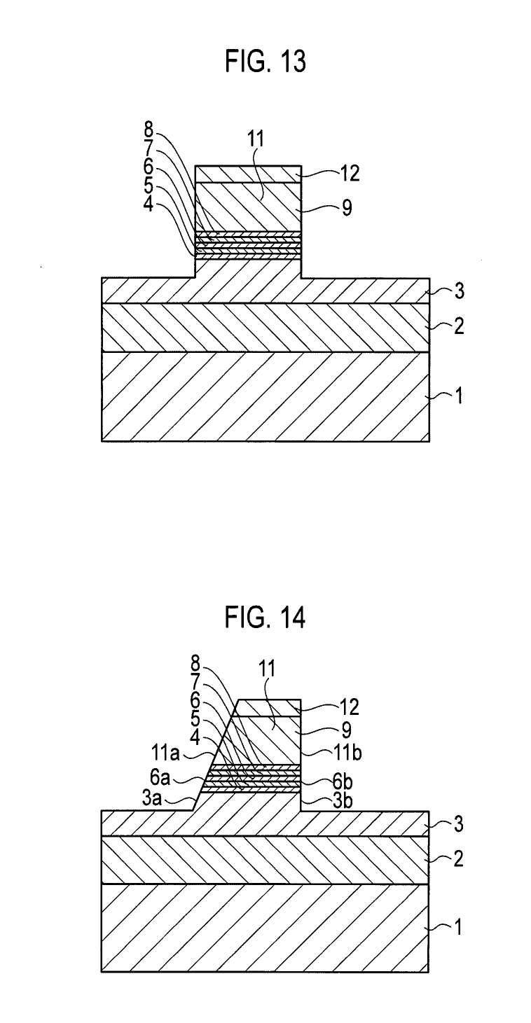

Next, as illustrated in FIG. 13, the SiO₂ film 21 is used as a mask to etch portions of the layers into a depth from the upper surface of the p-type cladding layer 9 to the midpoint of the n-type cladding layer 3 (depth of about 200 nm from the upper surface of the n-type cladding layer 3) by a dry etching technique using Cl₂ gas. At this time, a substrate temperature is maintained at about 200° C. As a result, a stripe-shaped ridge portion is formed, which is made of a projective portion of the n-type cladding layer 3 and layers formed thereon, and which has a width of about 1.3 μm. Herein, a side surface 3a, a side surface 6a, and a side surface 11a serve as a (000-1) N surface. A side surface 3b, a side surface 6b, and a side surface 11b serve as a (0001) Ga surface. They have surface orientations substantially perpendicular to a principal surface of the active layer.

Next, as illustrated in FIG. 14, the ridge side surfaces are etched using a aqua solution of KOH and so on. At this time, since the side surface 3a, the side surface 6a and the side surface 11a have the (000-1) surface, they are easily etched, and the side surface 3b, the side surface 6b and the side surface 11b have the chemically stable (0001) Ga surface, and therefore are little etched. Accordingly, the side surface 11a has a surface orientation inclined at 25° to 30° from the (000-1) N surface, while the side surface 11b has a surface orientation inclined at 5° or less from the (0001) Ga surface. As a result, the width of the active layer 6 is about 1.2 μm. Herein, two side surfaces of the active layer and the p-type semiconductor layer are formed to have different surface orientations from each other, thereby making it possible to easily set inclined angles of two side surfaces of the active layer and the p-side semiconductor layer to be different from each other.

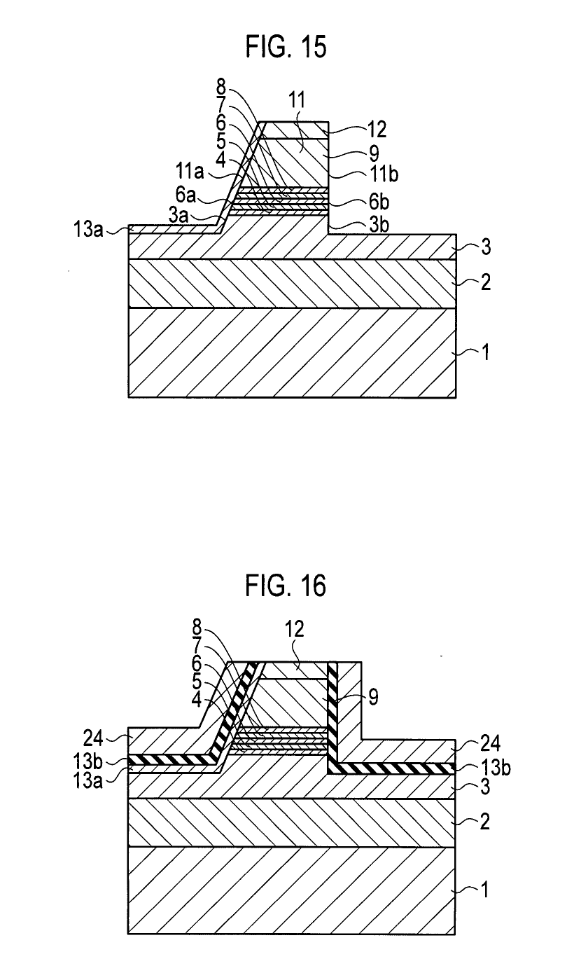

Next, as illustrated in FIG. 15, a current confinement layer 13a, made of a SiO₂ film with a thickness of about 250 nm, is formed to cover the flat portion of the n-type cladding layer 3 on the side of the side surface 3a, the side surface 3a, the side surface 6a, and the side surface 11a using a plasma CVD method. Then, a current confinement layer 13b, made of a Nb₂O₅ film with a thickness of about 250 nm, is formed to cover the entire surface of the flat portion of the n-type cladding layer 3, the side surface 3a, the side surface 6a, the side surface 11a as well as the flat portion of the n-type cladding layer 3 on the side of the side surface 3b, the side surface 3b, the side surface 6b and the side surface 11b. After that, a resist 24 is formed on a region except for the region corresponding to the ridge portion 11 on the current confinement layers 13a and 13b. Next, the resist 24 is used as a mask to etch the current confinement layers 13 positioned on the upper surface of the p-side ohmic electrode 12. Thus, a state shown in FIG. 16 is obtained. After that, the resist 24 is removed therefrom.

Next, a p-side pad electrode 14 is formed on a predetermined region of the current confinement 13 using a vacuum deposition method. Thus, the p-side pad electrode 14 comes in contact with the upper surface of the p-side ohmic electrode 12. Finally, as illustrated in FIG. 11, an n-side electrode 16 is formed on the back surface of the n-type GaN substrate 1 using the vacuum deposition method.

Then, the resultant is cleaved along a {1-100} surface, and the obtained cleavage surface is used as a cavity surface. In this way, the GaN semiconductor laser device according to the second embodiment is formed.

As mentioned above, according to the second embodiment, it is possible to manufacture the semiconductor laser device capable of easily adjusting angles of the side surfaces of the ridge portion to be a left-right asymmetry and reducing an operating voltage of the device while suppressing the occurrence of a kink.

### Third Embodiment

An oscillation wavelength of a GaN semiconductor laser device according to a third embodiment is about 410 nm.

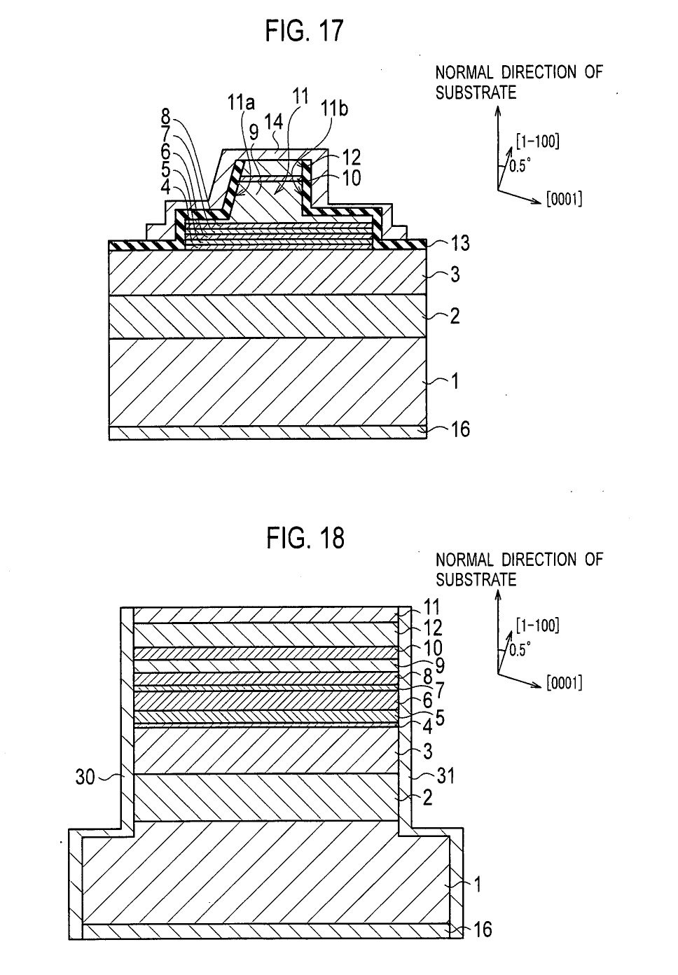

FIG. 17 is a cross-sectional diagram illustrating a GaN semiconductor laser device structure according to the third embodiment of the present invention. FIG. 18 is a cross-sectional diagram perpendicular to FIG. 17.

In the third embodiment, as illustrated in FIG. 17, an n-type layer 2 is formed on a Si-doped n-type GaN (1-100) misoriented substrate 1 having a thickness of about 100 μm and a carrier concentration of about 5×10¹⁸ cm⁻³. The n-type GaN (11-20) misoriented substrate is misoriented by 0.5° from (1-100) surface toward a [000-1] direction. The n-type layer 2 is made of Si-doped n-type GaN having a thickness of about 100 nm and a doping amount of about 5×10¹⁸ cm⁻³. On the n-type layer 2, an n-type cladding layer 3 is formed. The n-type cladding layer 3 is made of Si-doped n-type Al_{0.07}Ga_{0.93}N having a thickness of about 400 nm, a doping amount of about 5×10¹⁸ cm⁻³ and a carrier concentration of about 5×10¹⁸ cm⁻³.

On the n-type cladding layer 3, an n-type carrier blocking layer 4 is formed. The n-type carrier blocking layer 4 is made of Si-doped n-type Al_{0.16}Ga_{0.84}N carrier having a thickness of about 5 nm, a doping amount of about 5×10¹⁸ cm⁻³ and a carrier concentration of about 5×10¹⁸ cm⁻³. On the n-type carrier blocking layer 4, an n-type optical guide layer 5 is formed. The n-type optical guide layer 5 is made of Si-doped n-type GaN having a thickness of about 100 nm, a doping amount of about 5×10¹⁸ cm⁻³ and a carrier concentration of about 5×10¹⁸ cm⁻³.

On the n-type optical guide layer 5, an active layer 6 is formed. The active layer 6 has the same stacked structure as that of the first embodiment shown in FIG. 2.

Furthermore, as illustrated in FIG. 17, on the active layer 6, a p-type optical guide layer 7 is formed. The p-type optical guide layer 7 is made of Mg-doped p-type GaN having a thickness of about 100 nm, a doping amount of about 4×10¹⁹ cm⁻³ and a carrier concentration of about 5×10¹⁷ cm⁻³. On the p-type optical guide layer 7, a p-type cap layer 8 is formed. The p-type cap layer 8 is made of Mg-doped p-type Al_{0.16}Ga_{0.84}N having a thickness of about 20 nm, a doping amount of about 4×10¹⁹ cm⁻³ and a carrier concentration of about 5×10¹⁷ cm⁻³.

On the p-type cap layer 8, a p-type cladding layer 9 is formed. The p-type cladding layer 9 is made of Mg-doped p-type Al_{0.07}Ga_{0.93}N, and has a projective portion and flat portions continuous to both sides of the projective portion, a doping amount of about 4×10¹⁹ cm⁻³ and a carrier concentration of about 5×10¹⁷ cm⁻³. The thickness of the flat portion of the p-type cladding layer 9 is about 80 nm. Moreover, a height from the upper surface of the p-type cladding layer 9 to the flat portion is about 320 nm, and a width of the projective portion is 1.75 μm. On the projective portion of the p-type cladding layer 9, a p-type contact layer 10 is formed. The p-type contact layer 10 is made of Mg-doped p-type GaN having a thickness of about 10 nm, a doping amount of about 4×10¹⁹ cm⁻³ and a carrier concentration of about 5×10¹⁷ cm⁻³. A ridge portion 11 is formed of the p-type contact layer 10 and the projective portion of the p-type cladding layer 9. The ridge portion 11 has one side surface 11a and other side surface 11b opposite to the side surface 11a. Furthermore, the ridge portion 11 has a width of 1.75 μm at its lower portion, and is formed in a shape extending in a [11-20] direction. Note that, each of the p-type optical guide layer 7, the p-type cap layer 8, the p-type cladding layer 9, and the p-type contact layer 10, is one example of a “semiconductor layer” of the present invention. Moreover, the side surfaces 11a and 11b are examples of a “first side surface” and a “second side surface” of the present invention, respectively.

Herein, in the third embodiment, the side surface 11a has a surface orientation inclined at 25° to 30° from a (000-1) N surface. On the other hand, the side surface 11b has a surface orientation inclined at 5° or less from a (0001) Ga surface. Moreover, outside the side surfaces 11a and 11b, a first flat portion is formed. The first flat surface is formed of the semiconductor layer including the lower end portion of the ridge portion 11 to the upper surface of the active layer 6 (the flat portion of the p-type cladding layer 9, the p-type cap layer 8 and the p-type optical guide layer 7), and has a thickness of about 200 nm. In this respect, an inclined angle of the side surface 11a to the principal surface of the active layer 6 is made smaller than that of the side surface 11b to the principal surface of the active layer 6, thereby allowing an effective refractive index of the active layer 6 in the vicinity of the lower portion of the side surface 11a to be made smaller than that in the vicinity of the lower portion of the side surface 11b.

Moreover, on the p-type contact layer 10 that forms the ridge portion 11, a p-side ohmic electrode 12 is formed which has the same structure as that of the first embodiment. On a region except for the upper surface of the p-side ohmic electrode 12, a current confinement layer 13 is formed. The current confinement layer 13 is made of a SiO2 film having a thickness of about 250 nm. On a predetermined region of the current confinement layer 13, a p-side pad electrode 14 is formed in such a way to come into contact with the upper surface of the p-side ohmic electrode 12. The p-side pad electrode 14 has the same structure as that of the first embodiment.

Moreover, on the back surface of the n-type GaN substrate 1, an n-side electrode 16 is formed, having the same structure as that of the first embodiment.

Furthermore, as illustrated in FIG. 18, on each of both end portions of the ridge portion, a cavity surface is formed, and has a {11-20} plane. A dielectric multilayer film is formed on the cavity surface.

In the third embodiment, an inclined angle of the side surface 11a to the principal surface of the active layer 6 is made smaller than that of the side surface 11b to the principal surface of the active layer 6, whereby an effective refractive index of the active layer 6 in the vicinity of the lower portion of the side surface 11a is made smaller than that in the vicinity of the lower portion of the side surface 11b. It is, therefore, possible to increase the upper limit size of the width of the ridge portion 11 that enables to suppress the occurrence of higher-order horizontal transverse mode as compared with the case where the side surface 11a of the ridge portion 11 and the side surface 11b thereof have the same effective refractive index. This snakes it possible to increase the width of the ridge portion 11 while suppressing the occurrence of a kink caused by the occurrence of higher-order horizontal transverse mode. In this case, it is possible to increase a contact area between the p-type contact layer 10 that forms the ridge portion 11 and the p-side ohmic electrode 12 formed on the ridge portion 11, and therefore contact resistance between the p-type contact layer 10 and the p-side ohmic electrode 12 can be reduced. This makes it possible to reduce an operating voltage of the device while suppressing the occurrence of a kink. As a result, it is possible to reduce the operating voltage of the device while obtaining a good laser characteristic at the time of a high output operation.

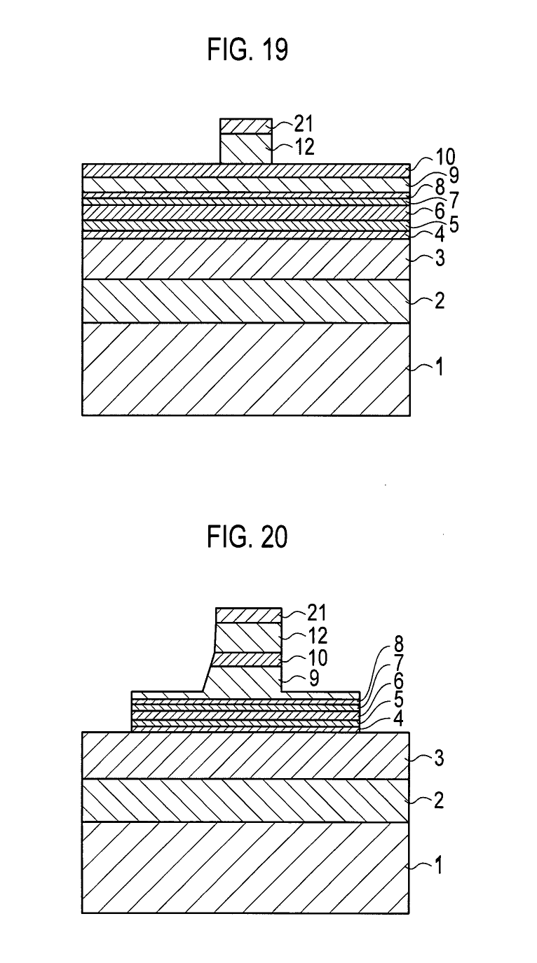

An explanation will be nest given of a GaN semiconductor laser device manufacturing according to the third embodiment with reference to FIGS. 19 and 20.

First, an n-type layer 2, an n-type cladding layer 3, and an n-type carrier blocking layer 4 are grown on an n-type GaN substrate 1 at 1100° C. using an MOVPE method. After that, an n-type optical guide layer 5, an active layer 6, a p-type optical guide layer 7, and a p-type cap layer 8 are grown on the n-type carrier blocking layer 4 at 800° C. Subsequently, a p-type cladding layer 9 having a thickness of about 400 nm and a p-type contact layer 10 are grown on the p-type cap layer 8 at 1100° C. After that, annealing is performed in a nitrogen gas atmosphere of under a temperature condition of about 850° C.

Next, a p-side ohmic electrode 12 is formed on the p-type contact layer 10 using an electron-beam evaporation method. After that, a SiO₂ film 21 having a thickness of about 250 nm is formed on the p-side ohmic electrode 12. Then, as illustrated in FIG. 19, the p-side ohmic electrode 12 and SiO₂ film 21 are patterned to form the p-side ohmic electrode 12 and SiO₂ film 21 in a stripe shape extending in a [11-20] direction and having a width of 1.75 μm.

Next, the SiO₂ film 21 is used as a mask to etch a portion of the layers into a depth from the upper surface of the p-type contact layer 10 to the midpoint of the p-type cladding layer 9 (depth of about 320 nm from the upper surface of the p-type cladding layer 9) by a dry etching technique using Cl₂ gas. At this time, a substrate temperature is maintained at about 200° C. As a result, a stripe-shaped ridge portion 11 is formed, which is formed of the p-type contact layer 10 and a projective portion of the p-type cladding layer 9, and which has a width of about 1.75 μm at its lower portion. Herein, a side surface 11a serves as a (000-1) N surface, and a side surface 11b serves as a (0001) Ga surface. They have surface orientations substantially perpendicular to the principal surface of the active layer 6. Next, a resist 22 is formed on flat portions of the p-type cladding layer 9 to cover the SiO₂ film 21, the p-side ohmic electrode 12 and the ridge portion 11. Then, the resist 22 is used as a mask to etch a portion from the upper surface of the flat portions of the p-type cladding layer 9 to the n-type carrier blocking layer 4. As a result, as illustrated in FIG. 20, the p-type cladding layer 9, the p-type cap layer 8, the p-type optical guide layer 7, the active layer 6, the n-type optical guide layer 5 and the n-type carrier blocking layer 4 are removed. After that, the resist 22 is removed therefrom.

Next, as illustrated in FIG. 20, the ridge side surfaces are etched using a solution such as KOH. At this time, since the side surface 11a has the (000-1) surface, it is easily etched. The side surface 11b has the chemically stable (0001) Ga surface, and therefore is little etched. As a result, the side surface 11a has a surface orientation inclined at 25° to 30° from the (000-1) N surface, while the side surface 11b has a surface orientation inclined at 5° or less from the (0001) Ga surface.

Next, a current confinement layer 13, made of a SiO₂ film with a thickness of about 250 nm, is formed to cover the entire surface of the layers including both side surfaces 11a and 11b of the ridge portion 11 using a plasma CVD method. After that, a resist is formed on a region except for the region corresponding to the ridge portion 11 on the current confinement layer 13. Next, the resist is used as a mask to etch the current confinement layer 18 positioned on the upper surface of the p-side ohmic electrode 12. After that, the resist is removed therefrom. Next, a p-side pad electrode 14 is formed on a predetermined region of the current confinement 13 using a vacuum deposition method. Thus, the p-side pad electrode 14 comes in contact with the upper surface of the p-side ohmic electrode 12.

After that, as illustrated in FIG. 17, an n-side electrode 16 is formed on the back surface of the n-type GaN substrate 1 using the vacuum deposition method. In this way, the GaN semiconductor laser device according to the third embodiment is formed.

Finally, as illustrated in FIG. 18, a cavity surface along a {11-20} surface is formed by a reactive ion beam etching method and the like.

Note that, in the third, embodiment, grooves extending in a [11-20] direction may be formed on the n-type GaN (1-100) misoriented substrate 1. The formation of grooves allows a crack generation in the [0001] direction to be suppressed.

As mentioned above, according to the third embodiment, it is possible to manufacture the semiconductor laser device capable of easily adjusting angles of the side surfaces of the ridge portion to be a left-right asymmetry and reducing an operating voltage of the device while suppressing the occurrence of a kink.

### Fourth Embodiment

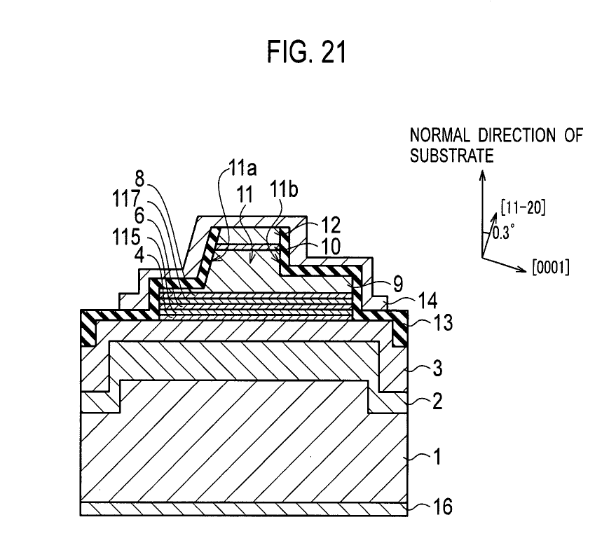

Next, a GaN semiconductor laser device structure according to this embodiment will be described with reference to FIG. 21. An oscillation wavelength of the GaN semiconductor laser device according to this embodiment is about 270 nm. The GaN semiconductor laser device according to this embodiment oscillates in a TE (horizontal polarization) mode.

In this embodiment, as illustrated in FIG. 21, a nitrogen-doped n-type 6H—SiC (11-20) misoriented substrate 1 has a thickness of about 100 μm and a carrier concentration of about 5×10¹⁸ cm⁻³, and is misoriented by 0.3° from (11-20) surface toward a [000-1] direction. Furthermore, on the n-type 6H—SiC (11-20) misoriented substrate 1, grooves are formed having a depth of about 0.5 μm extending in a [1-100] direction and a width of about 20 μm. These grooves are positioned at both ends of the semiconductor laser device. On a n-type layer 2, an n-type cladding layer 3 is formed. The n-type cladding layer 3 is made of Si-doped n-type Al_{0.45}Ga_{0.55}N having a thickness of about 400 mm, a doping amount of about 5×10¹⁸ cm⁻³ and a carrier concentration of about 1×10¹⁸ cm⁻³.

On the n-type cladding layer 3, an n-type carrier blocking layer 4 is formed. The n-type carrier blocking layer 4 is made of Si-doped n-type Al_{0.50}Ga_{0.50}N having a thickness of about 5 nm, a doping amount of about 5×10¹⁸ cm⁻³ and a carrier concentration of about 1×10¹⁸ cm⁻³. On the n-type carrier blocking layer 4, an n-side optical guide layer 115 is formed. The n-side optical guide layer 115 is made of Al_{0.40}Ga_{0.60}N optical having a thickness of about 100 nm.

On the n-side optical guide layer 115, an active layer 6 is formed. As illustrated in FIG. 2, the active layer 6 has an MQW structure in which two barrier layers 6a and three well layers 6b are stacked alternately. The barrier layer 6a is made of undoped Al_{0.40}Ga_{0.60}N having a thickness of about 20 nm. The well layer 6b is made of undoped Al_{0.53}Ga_{0.67}N having a thickness of about 3 nm.

Furthermore, as illustrated in FIG. 21, on the active layer 6, a p-side optical guide layer 117 is formed. The p-side optical guide layer 117 is made of Al_{0.40}Ga_{0.60}N having a thickness of about 100 nm. On the p-side optical guide layer 117, a p-type carrier blocking layer 8 is formed. The p-type carrier blocking layer 8 is made of Mg-doped p-type Al_{0.50}Ga_{0.50}N having a thickness of about 20 nm and a doping amount of about 4×10¹⁹ cm⁻³.

On the p-type carrier blocking layer 8, a p-type cladding layer 9 is formed. The p-type cladding layer 9 has a superlattice structure made of Mg-doped Al_{0.40}Ga_{0.60}N having a thickness of about 2 nm and a doping amount of about 4×10¹⁹ cm⁻³ and Mg-doped Al_{0.60}Ga_{0.40}N having a thickness of about 2 nm. A projective portion and flat portions continuous to both sides of the projective portion are formed therein.

The thickness of the flat portions of the p-type cladding layer 9 differs at both sides of the projective portion. Specifically, a left side of the projective portion is about 10 nm and a right side thereof is about 80 nm in the cross section shown in FIG. 1. Moreover, a height from the upper surface of the p-type cladding layer 9 to the lower surface of the flat portions is about 320 nm. A width of the projective portion is 1.15 μm at the lower surface.

On the projective portion of the p-type cladding layer 9, a p-type contact layer 10 is formed. The p-type contact layer 10 is made of Mg-doped p-type GaN having a thickness of about 10 nm, a doping amount of about 4×10¹⁹ cm⁻³ and a carrier concentration of about 5×10¹⁷ cm⁻³.

A ridge portion 11 is formed of the p-type contact layer 10 and the projective portion of the p-type cladding layer 9. The ridge portion 11 has one side surface 11a and other side surface 11b opposite to the side surface 11a. Furthermore, the ridge portion 11 is formed in a shape extending in a [1-100] direction. Note that, a p-type semiconductor layer, which is formed of the p-side optical guide layer 117, the p-type cap layer 8, the p-type cladding layer 9, and the p-type contact layer 10, is one example of a “semiconductor layer” of the present invention. Moreover, the side surfaces 11a and 11b are examples of the a “first side surface” and a “second side surface” of the present invention, respectively. Furthermore, the ridge portion 11 is one example of a “current path portion” of the present invention.

Furthermore, an inner angle of the side surface 11a as a side surface of the current path portion to the principal surface of the active layer 6 is different from that of the side surface 11b to the principal surface of the active layer 6 as in the case of the aforementioned first embodiment.

Moreover, on the p-type contact layer 10 that forms the ridge portion 11, a p-side ohmic electrode 12 is formed which is the same as that in the first embodiment. On a region except for the upper surface of the p-side ohmic electrode 12, a current confinement layer 13 is formed. The current confinement layer 13 is made of a SiO2 film (insulating film) having a thickness of about 250 nm. On a predetermined region of the current confinement layer 13, a p-side pad electrode 14 is formed which is the same as that in the first embodiment. Moreover, on the back surface of the n-type 6H—SiC (11-20) substrate 1, an n-side electrode 16 is formed which is the same as that in the first embodiment.

Furthermore, a cavity surface is formed on each of both end portions of the ridge portion 11. The cavity surface is made of a {1-100} surface cleavage surface. A dielectric multilayer film with a reflectivity of 5% is formed on the cavity surface on a laser beam emission surface side, and a dielectric multilayer film with a reflectivity of 95% is formed on the cavity surface on an opposite side.

An explanation will be next given of a GaN semiconductor laser device manufacturing method according to this embodiment.

First, on an n-type 6H—SiC (11-20) misoriented substrate 1, grooves are formed at an interval of about 400 μm. Each groove has a depth of about 0.5 μm extending in a [1-100] direction and a width of about 40 μm.

Next, in the same condition as that of the first embodiment, an n-type layer 2, an n-type cladding layer 3, an n-type carrier blocking layer 4, an n-type optical guide layer 115, an active layer 6, a p-side optical guide layer 117, a p-type cap layer 8, a p-type cladding layer 9, and a p-type contact layer 10 are sequentially grown on the n-type 6H—SiC (11-20) misoriented substrate 1 using an MOVPE method.

Afterward, the same processing as that of the first embodiment is carried out to form the GaN semiconductor laser device according to this embodiment.

In the active layer 6 according to this embodiment, Δ_{cr} (crystal field splitting energy in a valence band) of material that forms the well layer 6 in the quantum well structure is negative. Accordingly, in the quantum well structure of this embodiment, a hole ground state mainly comprises a C-band having symmetry of Γ₇. For this reason, oscillator strength of the transition into the hole ground state for the light linearly polarized in the c-axis direction is larger than that for the light linearly polarized in the c-axis direction. As a result, the GaN semiconductor laser device according to this embodiment oscillates in the TE mode. In this respect, in order to obtain negative Δ_{cr}, Al composition of the well layer 6b is preferably 0.32 or more.

### Fifth Embodiment

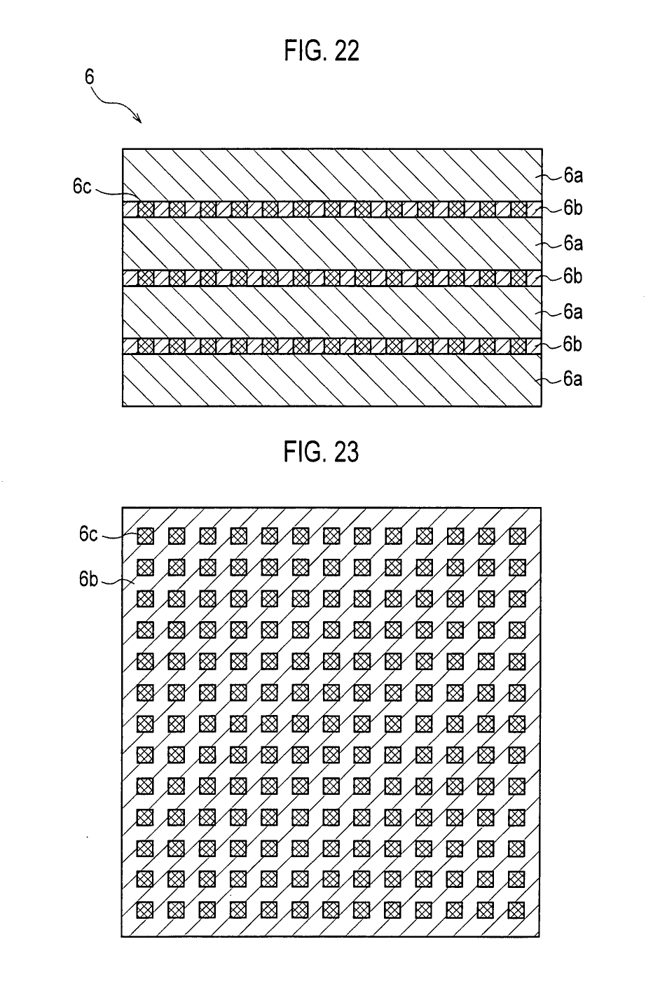

An explanation will be next given of a GaN semiconductor laser device according to this embodiment using FIG. 22. FIG. 22 is enlarged cross-sectional diagram of an active layer 6 of the GaN semiconductor laser device according to this embodiment. The other layers except for the active layer 6 are the same as those of the aforementioned first embodiment. An oscillation wavelength of the GaN semiconductor laser device according to this embodiment is about 410 nm.

The active layer 6 having quantum dots structure is formed on an n-type optical guide layer 5. As illustrated in FIG. 22, the active layer 6 includes four barrier layers 6a, barrier layers 6b and box-shaped well layers 6c. The barrier layers 6b and well layers 6c are disposed between the barrier layers 6a. The barrier layer 6a is made of undoped In_{0.02}Ga_{0.90}N having a thickness of about 20 nm. The barrier layer 6b is made of undoped In_{0.10}Ga_{0.80}N having a thickness of 3 nm. The well layer 6c is made of undoped In_{0.20}Ga_{0.80}N having a substantially cubic shape (about 3 nm on each edge). FIG. 23 is a plane diagram illustrating a portion including the barrier layer 6b and the box-shaped well layers 6c that are disposed between the barrier layers 6a.

The active layer 6 according to this embodiment has the quantum dot structure, and therefore makes it possible to increase oscillator strength for light linearly polarized in an a-axis or c-axis direction. In other words, the GaN semiconductor laser device according to this embodiment can increase a gain for TM mode or TE mode.

### Sixth Embodiment

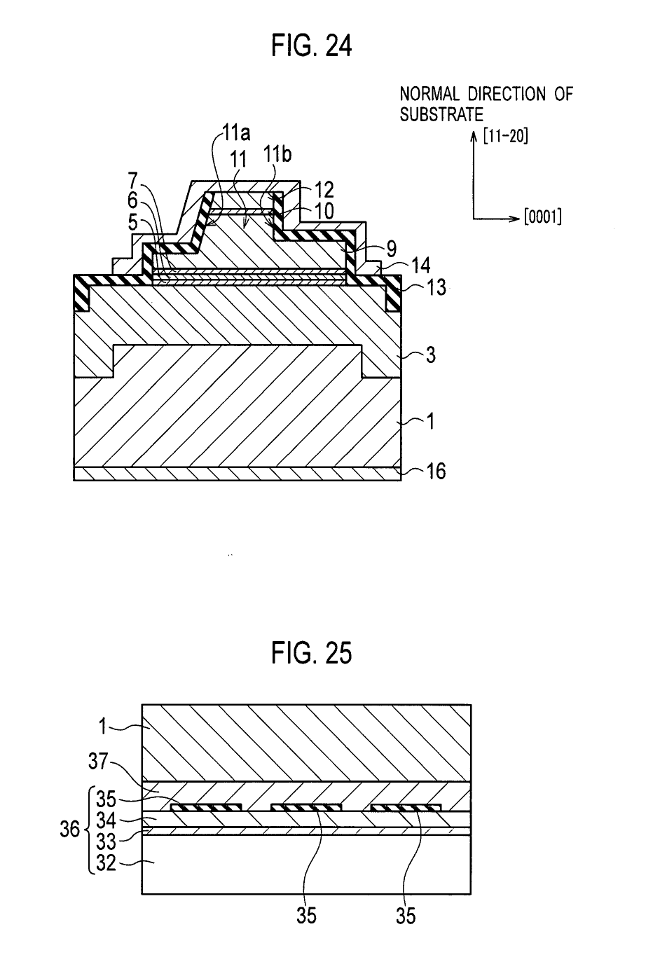

Next, a GaN semiconductor laser device structure of this embodiment will be described with reference to FIG. 24. FIG. 24 is a cross-sectional diagram illustrating the GaN semiconductor laser device structure of this embodiment. In this embodiment, an active layer 6 is a quantum well made of a well layer having tensile strain. An oscillation wavelength of the GaN semiconductor laser device of this embodiment is about 530 nm. The GaN semiconductor laser device according to this embodiment oscillates in a TM (vertical polarization) mode.

As illustrated in FIG. 24, in the GaN semiconductor laser device of this embodiment, an InGaN (11-20) surface substrate 1 is made of In_{0.85}Ga_{0.15}N having a thickness of about 50 μm to 200 μm. On the InGaN (11-20) surface substrate 1, an n-type cladding layer 3 is formed. The n-type cladding layer 3 is made of Si-doped In_{0.10}Ga_{0.90}N having a thickness of about 1 μm. Furthermore, on the InGaN (11-20) surface substrate 1, grooves are formed. Each groove has a depth of about 0.5 μm and a width of about 20 μm, and it is extending in the [1-100] direction. Each groove is positioned at both ends of the semiconductor laser device. On the n-type cladding layer 3, an n-type optical guide layer 5 is formed. The n-type optical guide layer 5 is made of Si-doped In_{0.15}Ga_{0.85}N having a thickness about 50 nm. On the n-type optical guide layer 5, an active layer 6 having an MQW structure is formed. The active layer 6 is formed such that two In_{0.30}Ga_{0.70}N quantum well layers having a thickness of about 2.5 nm and three In_{0.17}Ga_{0.83}N barrier layers having a thickness of about 15 nm are layered alternately.

Furthermore, on the active layer 6, a p-side optical guide layer 127 is formed. The p-side optical guide layer 127 is made of an undoped In_{0.15}Ga_{0.85}N having a thickness of about 50 nm. On the p-side optical guide layer 127, a p-type cladding layer 9 with a superlattice structure is formed with 60 cycles of an Mg doped In_{0.10}Ga_{0.90}N layer having a thickness of about 2.5 nm and a GaN layer having a thickness of about 2.5 nm.

The p-type cladding layer 9 has a projective portion and flat portions continuous to both sides of the projective portion as illustrated in FIG. 24. The thickness of the flat portions of the P-type cladding layer 9 differs at both sides of the projective portion. Specifically, a left side of the projective portion is about 10 nm, and a right side thereof is about 80 nm in the cross section shown in FIG. 24. Moreover, a height from the upper surface of the p-type cladding layer 9 to the lower surface of the flat portions is about 320 nm.

On the projective portion of the p-type cladding layer 9, a p-type contact layer 10 is formed. The p-type contact layer 10 is made of a Mg-doped p-type GaN having a thickness of about 0.1 μm.

A ridge portion 11 is formed of the p-type contact layer 10 and the projective portion of the p-type cladding layer 9. The ridge portion 11 has one side surface 11a and other side surface 11b opposite to the side surface 11a. Furthermore, the ridge portion 11 is formed in a stripe shape (long and narrow) extending in a light emitting direction as seen from the plane. Moreover, the ridge portion 11 has a width of 2.3 μm at its lower portion, and is formed in a shape extending in a [1-100] direction. Note that, a p-type semiconductor layer, which is formed of the p-side optical guide layer 127, the p-type cladding layer 9, and the p-type contact layer 10, is one example of a “semiconductor layer” of the present invention. Moreover, the side surfaces 11a and 11b are examples of the a “first side surface” and a “second side surface” of the present invention, respectively. In addition, the ridge portion 11 is one example of a “current path portion” of the present invention.

Furthermore, an inner angle of the side surface 11a as a side surface of the current path portion to the principal surface of the active layer 6 is different from that of the side surface 11b to the principal surface of the active layer 6 as in the case of the aforementioned first embodiment.

The other structures are the same as those of the first embodiment.

An explanation will be next given of a GaN semiconductor laser device manufacturing method according to this embodiment using FIG. 25.

First, as illustrated in FIG. 25, on a sapphire (1-102) R misoriented substrate 32 as a growth substrate, a low-temperature buffer layer 33 and a GaN layer 34 are sequentially grown using an HVPE (Halide Vapor Phase Epitaxy) method. In this respect, a crystal growth surface of the GaN layer 34 is a (11-20) surface, and all crystal growth of a nitride semiconductor layer grown on the GaN layer 34 is hereinafter performed on this (11-20) surface.

Specifically, the GaN low-temperature buffer layer 33, having a thickness of about 20 nm, is grown on the sapphire substrate 32 maintained at about 500° C. Then, the GaN layer 34 having a thickness of about 2 μm is grown with temperature maintained at about 1050° C.

Next, a SiO₂ film 35 is formed on the GaN layer 34 using a plasma CVD method. After that, openings with a diameter of 2 μm corresponding to a square lattice pattern are formed at an interval of about 10 μm using the known lithography technique. As a result, a base 36 for a selective-growth is formed made of the sapphire substrate 32, the low-temperature buffer layer 33, the GaN layer 34 and the SiO₂ film 35.

After that, as illustrated in FIG. 25, with the base 36 maintained at about 750° C., an InGaN layer 37 is selectively and laterally grown on the GaN layer 34 and SiO₂ film 35. The InGaN layer 37 is made of In_{0.30}Ga_{0.70}N having a thickness of about 20 μm. As a result of a lateral growth of the InGaN layer 37, layers grown on the surface of the GaN layer 34 exposed from SiO₂ films 35 coalesce each other and the surface of the InGaN layer 37 is finally flattened.

Next, with a temperature maintained at about 750° C., an InGaN layer (substrate 1) is grown. The InGaN layer is made of Si-doped In_{0.85}Ga_{0.15}N having a thickness of about 200 μm.

Then, the growth substrate made of the sapphire substrate 32, the low-temperature buffer 33, the GaN layer 34, SiO₂ film 35, and the InGaN layer 37 are removed by polishing to expose the back surface of the InGaN layer (substrate 1), and the resultant is used as InGaN (11-20) surface substrate 1. After that, a growth surface of the InGaN substrate 1 is polished by a thickness of about 0.5 μm using CMP (Chemical Mechanical Polishing). Moreover, the growth surface of the InGaN substrate 1 is removed by a thickness of about 0.5 μm by RIE etching using Cl₂, so that the growth surface of the InGaN substrate 1 is like a surface of a mirror.

Then, on the InGaN substrate 1, grooves are formed at an interval of about 400 μm. Each groove has a depth of 0.5 μm and a width of about 40 μm, and it is extending in a [1-100] direction.

Next, with the InGaN substrate 1 maintained at about 750° C., an n-type cladding layer 3 is grown on the InGaN substrate 1 in an atmosphere of NH₃ (25%) and H₂ (75%) using a MOVPE method. The n-type cladding layer 3 is made of Si doped n-type In_{0.10}Ga_{0.90}N having a thickness about 1 μm. After that, on the n-type cladding layer 3, there are subsequently grown a Si doped In_{0.15}Ga_{0.85}N n-type optical guide layer 5, an active layer 6 having an MQW structure, an undoped In_{0.15}Ga_{0.85}N p-side optical guide layer 127, a p-type cladding layer 9 with a superlattice structure with 60 cycles of a Mg-doped In_{0.10}Ga_{0.90}N layer having a thickness of about 2.5 nm and a GaN layer having a thickness of about 2.5 nm, and a Mg-doped p-type GaN contact layer 10 having a thickness of about 0.1 μm.

Afterward, the same processing as that of the first embodiment is carried out to form the GaN semiconductor laser device according to this embodiment.

In general, when in-plane tensile strain is applied to a quantum well having a (H, K, −H−K, 0) surface as a principal surface, it is possible to increase oscillator strength of the transition into the hole ground state for the light linearly polarized in the [H, K, −H−K, 0] direction. Accordingly, a gain for TM mode is increased.

The active layer 6 of this embodiment has an In_{0.30}Ga_{0.70}N quantum well layer on the In_{0.85}Ga_{0.15}N (11-20) surface substrate 1. Here, since the lattice constant of the In_{0.30}Ga_{0.70}N well layer is smaller than that of the In_{0.85}Ga_{0.15}N substrate, the quantum well layer has tensile strain. Since the quantum well layer has the tensile strain, in the quantum well structure of this embodiment, oscillator strength of the transition into the hole ground state for the light linearly polarized in the a-axis direction is larger than that for the light linearly polarized in the c-axis direction. As a result, the GaN semiconductor laser device according to this embodiment oscillates in the TM mode in which the direction of linear polarization of light is perpendicular to the principal plane of the active layer.

### Other Embodiments

The present invention is described according to the aforementioned embodiments; however, it should not be understood that the description and drawings that form part of this disclosure are to limit the present invention. This disclosure makes clear a variety of alternative embodiments, working examples, and operational techniques for those skilled in the art.

For example, in the foregoing first to third embodiments have explained about the example in which the present invention is applied to the GaN semiconductor laser device. However, the present invention is not limited to the foregoing device and is applicable to a semiconductor laser device including a wurtzite structure, such as ZnO based semiconductor.

Furthermore, in the foregoing first to third embodiments, the side surfaces of the ridge have been etched using a solution such as KOH or NaOH. However, etchant is not limited to these, and solutions such as RbOH or CsOH as alkali etchant or alkali etchant in which hydrogen peroxide is added to KOH or NaOH may be used. Or, acid etchant such as aqua regia, hydrochloric acid, etc. may be used.

Moreover, in the foregoing first to third embodiment, the current confinement layer made of dielectric has been formed. However, the present invention is not limited to this and a current confinement layer made of a semiconductor may be formed.

Furthermore, in the foregoing first to third embodiments, the surface orientation, which is inclined at an off angle from the (11-20) surface or (1-100) surface, has been used as the principal surface of the active layer. However, a singular surface of (11-20) or (1-100) surface may be used. Moreover, the direction of the misorientation is not limited to the direction described in the aforementioned first to third embodiments. For example, the surface orientation misoriented from (11-20) surface toward the [1-100] direction or the surface orientation misoriented from (1-100) surface toward the [11-20] direction may be used. Furthermore, the misorientation angle is not limited to the angle described in the aforementioned first to third embodiments. For example, it may be possible to use a range from 0.05° to 20°.

Moreover, in the foregoing first to third embodiments, the (11-20) surface or (1-100) surface has been used as the principal surface of the active layer. However, an (H, K, −H−K, 0) surface may be used. Or, it may be possible to use a surface misoriented by 0.05 to 20° from the (H, K, −H−K, 0) surface.

Furthermore, in the foregoing first to third embodiments, the GaN substrate has been used as the growth substrate. However, the present invention is not limited to this, and a (H, K, −H−K, 0) surface substrate made of other hexagonal materials may be used. For example, it may be possible to use an AlN (11-20) surface substrate and an a-SiC (11-20) surface substrate. In this case, a conductive substrate is preferably used and, in particular, an n-type substrate is preferably used. Moreover, a p-side electrode is formed and then connected to a support substrate made of Cu—W and the like. Thereafter, the growth substrate is removed therefrom and an n-side electrode may be formed on an exposed n-type layer.

Furthermore, in the present embodiments, structural layers of the semiconductor light emitting device have been formed using the MOVPE method. However, the present invention is not limited to this method, and may use other manufacturing methods, for example, MBE method, and deposition method such as sputtering method, laser ablation method.

Moreover, in the fourth embodiment, the active layer 6 has been formed to have the quantum well structure. However, it may be possible to use a single-layered active layer of material for which Δ_{cr} is negative, even in that case it can be reasonably expected that a hole ground state comprises mainly the C-band. For example, the active layer is made of AlGaN of which Al composition is 0.32 or more.

Furthermore, in the fifth embodiment, the active layer 6 has been formed to have the quantum dot structure. However, the active layer 6 may be formed to have a quantum wire structure.

Furthermore, in the sixth embodiment, the active layer 6 has been formed to have the quantum well structure. However, the active layer 6 may be formed to have a single-layered structure to which in-plane tensile strain is applied.

It is therefore needless to say that the present invention includes various other embodiments which are not described herein. Accordingly the technical scope of the present invention is determined only by specified features of the invention according to the following claims that can be regarded appropriate from the above-mentioned descriptions.

What is claimed is:

1. A semiconductor laser device comprising:
an active layer,
a semiconductor layer formed on the active layer and having a wurtzite structure, wherein
a principal surface of the active layer is substantially perpendicular to a (0001) surface of the semiconductor layer,
a current path portion in the semiconductor layer extends along a crystal orientation substantially parallel to the (0001) surface of the semiconductor layer, and
an inner angle of the principal surface to a first side surface is different from an inner angle of the principal surface to a second side surface, the first side surface is a side surface of the current path portion and the second side surface is opposite to the first side surface.

2. The semiconductor laser device according to claim 1, wherein
the semiconductor layer is made of a nitride semiconductor,
the first side surface is an N-polarity surface, and
the second side surface is a Ga-polarity surface.

3. The semiconductor laser device according to claim 1, wherein the semiconductor layer includes a projective portion having the first side surface and the second side surface.

4. The semiconductor laser device according to claim 3, wherein the semiconductor layer includes two flat portions continuously formed both side of the projective portion, and thickness of the two flat portions are different from each other.

5. The semiconductor laser device according to claim 1, wherein side surfaces of the active layer are formed on the same plane as those of the current path portion.

6. The semiconductor laser device according to 1, wherein the principal surface of the active layer is substantially parallel to a (11-20) surface of the semiconductor layer, and has a cleavage surface, being parallel to a (1-100) surface of the semiconductor layer, as a cavity surface.

7. The semiconductor laser device according to claims 1, wherein the active layer is formed on a (11-20) surface of a substrate which is made of a semiconductor having a hexagonal structure.

8. The semiconductor laser device according to claims 1, wherein
the active layer has a multiple quantum well structure including well layers and barrier layers which are laminated,
crystal field splitting energy of material that forms the well layers is negative.

9. The semiconductor laser device according to claims 1, wherein
the active layer is formed to have a single-layered structure,
crystal field splitting energy of material that forms the active layer is negative.

10. The semiconductor laser device according to claims 1, wherein
the active layer has a multiple quantum well structure including well layers and barrier layers which are laminated,
the well layers is made of AlGaN,
Al composition of the well layer is 0.32 or more.

11. The semiconductor laser device according to claims 1, wherein
the active layer is formed to have a single-layered structure,
the active layer is made of AlGaN,
Al composition of the active layer is 0.32 or more.

12. The semiconductor laser device according to claims 1, wherein
a hole ground state in the active layer is a C-band.

13. The semiconductor laser device according to claims 1, wherein
the active layer is formed to have a quantum dot structure or a quantum wire structure.

14. The semiconductor laser device according to claims 1, wherein
the active layer has a multiple quantum well structure including well layers and barrier layers which are laminated, in-plane tensile strain is applied to a well layer.

15. The semiconductor laser device according to claims 1, wherein
the active layer is formed to have a single-layered structure, in-plane tensile strain is applied to a well layer.

16. The semiconductor laser device according to claims 15, wherein
the semiconductor devise oscillates in the TM mode.

17. A method for manufacturing a semiconductor laser device, comprising the steps of:
forming a semiconductor layer having a wurtzite structure on a active layer, a principal surface of the active layer is substantially perpendicular to a (0001) surface of the semiconductor layer; and
forming, in the semiconductor layer, a current path portion extending along a crystal orientation substantially parallel to the (0001) surface of the semiconductor layer,
wherein forming the current path portion includes forming a first side surface as a side surface of the current path portion and a second side surface opposite to the first side surface by anisotropic etching, while the first side surface and the second side surface having different surface orientations from each other.
